(19) United States
(12) Patent Application Publication
(10) Pub. No.: US 2024/0170395 A1
(43) Pub. Date: May 23, 2024

(54) STAGGERED SIGNAL LINE INTERCONNECT STRUCTURE

(71) Applicant: International Business Machines Corporation, Armonk, NY (US)

(72) Inventors: Nicholas Anthony Lanzillo, Wynantskill, NY (US); Ruilong Xie, Niskayuna, NY (US); Huai Huang, Clifton Park, NY (US); Hosadurga Shobha, Niskayuna, NY (US); Lawrence A. Clevenger, Saratoga Springs, NY (US)

(21) Appl. No.: 18/056,739

(22) Filed: Nov. 18, 2022

(51) Int. Cl. H01L 23/522; H01L 21/768

(52) U.S. Cl. CPC H01L 23/5226; H01L 21/76802; H01L 21/76843; H01L 21/76877

(57) ABSTRACT

A semiconductor interconnect structure and formation thereof. The semiconductor interconnect structure includes a first row of metal lines located in a bottom portion of a metal layer and a second row of metal lines located in a top portion of the metal layer. The first row of metal lines are horizontally staggered with respect to the second row of metal lines.

### BACKGROUND OF THE INVENTION

The present invention relates generally to the field of semiconductor devices, and more particularly to an interconnect structure having staggered signal lines.

An integrated circuit (IC) device may be formed with millions of transistors and other circuit elements that are fabricated on a single silicon crystal substrate (wafer). For the IC device to be functional, multi-level or multi-layered interconnection schemes such as, for example, metal wiring formed by single damascene processes, dual damascene processes, subtractive etch processes, and combinations thereof, are fabricated in the back-end-of-the-line (BEOL) of the device to connect the circuit elements distributed on the surface of the device.

As ICs continue to move to smaller technology nodes, the ability to maintain and/or increase signal density to meet performance demands becomes increasingly challenging, especially when forming signal interconnects in the lower metal layers of the BEOL.

### SUMMARY

According to one embodiment of the present invention, a semiconductor interconnect structure is provided. The semiconductor interconnect structure includes a first row of metal lines located in a bottom portion of a metal layer and a second row of metal lines located in a top portion of the metal layer. The first row of metal lines are horizontally staggered with respect to the second row of metal lines.

According to another embodiment of the present invention, a semiconductor interconnect structure is provided. The semiconductor interconnect structure includes a first row of metal lines located between a pair of metal lines. The first row of metal lines are formed in a bottom portion of a metal layer and the pair of metal lines are formed in both the bottom portion of the metal layer and a top portion of the metal layer.

### BRIEF DESCRIPTION OF THE SEVERAL VIEWS OF THE DRAWINGS

The following detailed description, given by way of example and not intend to limit the disclosure solely thereto, will best be appreciated in conjunction with the accompanying drawings, in which:

FIG. 1A illustrates a cross-sectional view of an initial semiconductor structure, generally designated 100, including a dielectric layer 120 formed on a substrate 110 in accordance with at least one embodiment of the present invention.

FIG. 1B illustrates a cross-sectional view of semiconductor structure 100A depicted in FIG. 1A after performing subsequent processing steps, generally designated 100B, in accordance with at least one embodiment of the present invention.

FIG. 1C illustrates a cross-sectional view of semiconductor structure 100B depicted in FIG. 1B after performing subsequent processing steps, generally designated 100C, in accordance with at least one embodiment of the present invention.

FIG. 1D illustrates a cross-sectional view of semiconductor structure 100C depicted in FIG. 1C after performing subsequent processing steps, generally designated 100D, in accordance with at least one embodiment of the present invention.

FIG. 1E illustrates a cross-sectional view of semiconductor structure 100D depicted in FIG. 1D after performing subsequent processing steps, generally designated 100E, in accordance with at least one embodiment of the present invention.

FIG. 1F illustrates a cross-sectional view of semiconductor structure 100E depicted in FIG. 1E after performing subsequent processing steps, generally designated 100F, in accordance with at least one embodiment of the present invention.

FIG. 2A illustrates a cross-sectional view of an initial semiconductor structure, generally designated 200A, including substrate 110 and conductive metal layer 120, in accordance with at least one embodiment of the present invention.

FIG. 2B illustrates a cross-sectional view of semiconductor structure 200A depicted in FIG. 2A after performing subsequent processing steps, generally designated 200B, in accordance with at least one embodiment of the present invention.

FIG. 2C illustrates a cross-sectional view of semiconductor structure 200B depicted in FIG. 2B after performing subsequent processing steps, generally designated 200C, in accordance with at least one embodiment of the present invention.

FIG. 2D illustrates a cross-sectional view of semiconductor structure 200C depicted in FIG. 2C after performing subsequent processing steps, generally designated 200D, in accordance with at least one embodiment of the present invention.

FIG. 2E illustrates a cross-sectional view of semiconductor structure 200D depicted in FIG. 2D after performing subsequent processing steps, generally designated 200E, in accordance with at least one embodiment of the present invention.

FIG. 2F illustrates a cross-sectional view of semiconductor structure 200E depicted in FIG. 2E after performing subsequent processing steps, generally designated 200F, in accordance with at least one embodiment of the present invention.

FIG. 3A illustrates a cross-sectional view of an initial semiconductor structure, generally designated 300A, including substrate 110 and conductive metal layer 120, in accordance with at least one embodiment of the present invention.

FIG. 3B illustrates a cross-sectional view of semiconductor structure 300A depicted in FIG. 3A after performing subsequent processing steps, generally designated 300B, in accordance with at least one embodiment of the present invention.

FIG. 3C illustrates a cross-sectional view of semiconductor structure 300B depicted in FIG. 3B after performing subsequent processing steps, generally designated 300C, in accordance with at least one embodiment of the present invention.

FIG. 3D illustrates a cross-sectional view of semiconductor structure 300C depicted in FIG. 3C after performing subsequent processing steps, generally designated 300D, in accordance with at least one embodiment of the present invention.

FIG. 3E illustrates a cross-sectional view of semiconductor structure 300D depicted in FIG. 3D after performing subsequent processing steps, generally designated 300E, in accordance with at least one embodiment of the present invention.

FIG. 3F illustrates a cross-sectional view of semiconductor structure 300E depicted in FIG. 3E after performing subsequent processing steps, generally designated 300F, in accordance with at least one embodiment of the present invention.

FIG. 4A illustrates a cross-sectional view of an initial semiconductor structure, generally designated 400A, including substrate 110, dielectric layer 420, and line openings 411, 413, and line openings 421, 423, 423, 423, in accordance with at least one embodiment of the present invention.

FIG. 4B illustrates a cross-sectional view of semiconductor structure 400A depicted in FIG. 4A after performing subsequent processing steps, generally designated 400B, in accordance with at least one embodiment of the present invention.

FIG. 4C illustrates a cross-sectional view of semiconductor structure 400B depicted in FIG. 4B after performing subsequent processing steps, generally designated 400C, in accordance with at least one embodiment of the present invention.

FIG. 4D illustrates a cross-sectional view of semiconductor structure 400C depicted in FIG. 4C after performing subsequent processing steps, generally designated 400D, in accordance with at least one embodiment of the present invention.

FIG. 4E illustrates a cross-sectional view of semiconductor structure 400D depicted in FIG. 4D after performing subsequent processing steps, generally designated 400E, in accordance with at least one embodiment of the present invention.

FIG. 4F illustrates a cross-sectional view of semiconductor structure 400E depicted in FIG. 4E after performing subsequent processing steps, generally designated 400F, in accordance with at least one embodiment of the present invention.

FIGS. 5-8, generally designated 500, 600, 700, and 800, respectfully, are methods of fabricating semiconductor interconnect structures corresponding to the semiconductor structures described with reference to FIGS. 1A-1F . . . 4A-4F. The methods 500-800 may be used in conjunction with, for example, any of the exemplary fabrication sequences of FIGS. 1A-1F . . . 4A-4F.

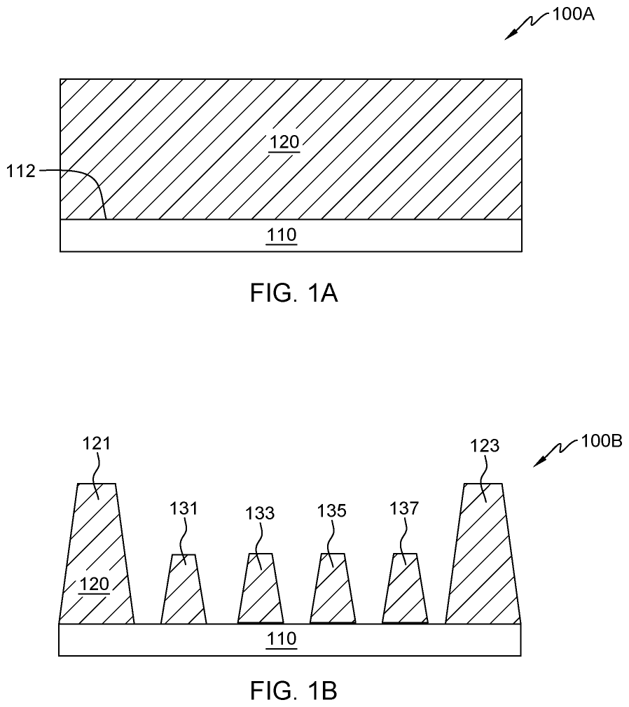

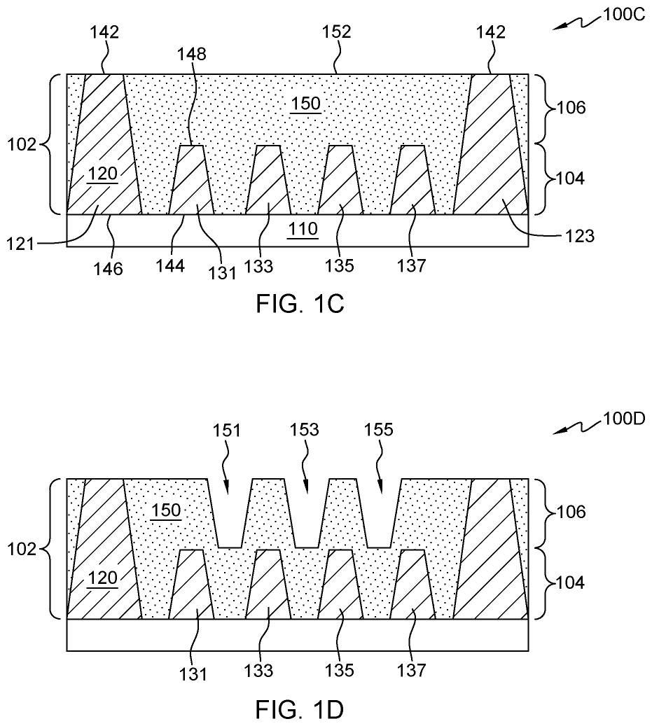

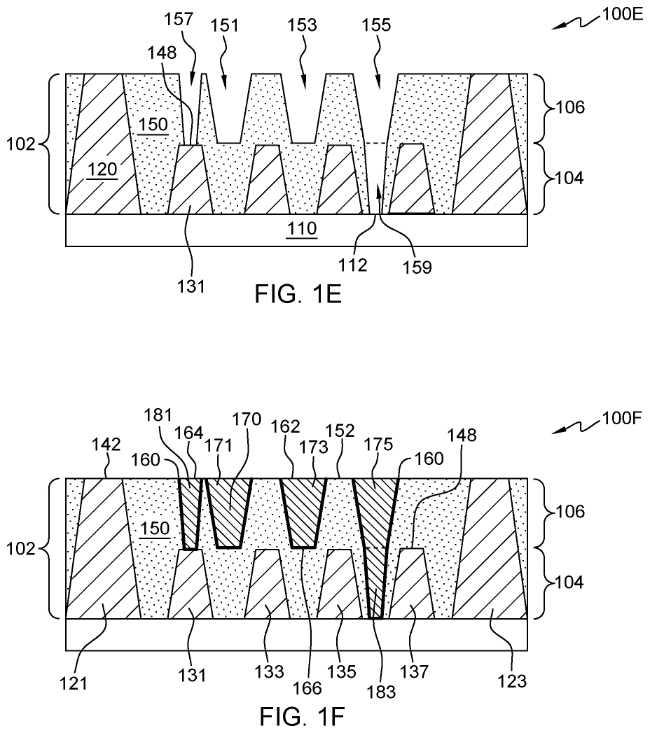

When viewed as ordered combinations, FIGS. 1A-1F . . . 4A-4F, and 5-8 illustrate both (i) semiconductor devices and (ii) the methods for forming such semiconductor devices, in accordance with illustrative embodiments.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Embodiments of the present invention provide for a semiconductor device having a first row of lines located in a bottom portion of a metal layer of a multilevel interconnect structure and a second row of lines located in a top portion of the metal layer of the multilevel interconnect structure. The first row of lines located in the bottom portion of the metal layer of the multilayer interconnect structure are horizontally staggered with respect to the second row of lines located in the top portion of the metal layer of the multilayer interconnect structure. By horizontally staggering multiple vertically stacked rows of lines within the same metal layer, the signal track density within a single metal layer of the multilayer interconnect structure may be increased by as much as fifty percent.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

As described below, in conjunction with FIGS. 1A . . . 1F-4A . . . 4F, embodiments of the present invention include semiconductor interconnect structures and methods of forming such semiconductor interconnect structures, and in particular, semiconductor interconnect structures having horizontally staggered vertically stacked rows of lines formed within the same metal layer of a multilayer interconnect structure. The methods described below in conjunction with FIGS. 1A . . . 1F-4A . . . 4F may be incorporated into typical semiconductor memory device fabrication processes. As such, when viewed as ordered combinations, FIGS. 1A . . . 1F-4A . . . 4F illustrate methods for forming semiconductor interconnect structures having increased signal track density within a single metal layer of a multilayer interconnect structure.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of microcooler device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, exposure to a specific frequency or range of frequencies of electromagnetic radiation, ion implantation techniques, and/or chemical/mechanical polishing (CMP). As used herein, terms, such as “forming,” and the like, may refer to processes that alter the structure of one or more layers of material, or portions of material(s), by removal of a quantity of material, in accordance with a given embodiment. For example, such formation processes may include, but are not limited to, micromachining, microetching, wet and/or dry etching processes, plasma etching processes, or any of the known etching processes in which material is removed.

Those skilled in the art understand that many different techniques may be used to add, remove, and/or alter various materials, and portions thereof, and that embodiments of the present invention may leverage combinations of such processes to produce the structures disclosed herein without deviating from the scope of the present invention.

As used herein, the term signal via may refer to a via that carries signals between two different lines located in two different metal layers. For example, a signal via may transfer signals from a first line located in a first metal layer to a second line located in a second metal layer.

As used herein, the term power via may refer to a via that carries power between two different lines located in two different metal layers. For example, a power via may transfer power (i.e., power and/or ground) from a first line located in a first metal layer to a second line located in a second metal layer.

As used herein, the term signal line may refer to a line (i.e., metal line or interconnect) in the back-end-of-the-line (BEOL) of a semiconductor device used to distribute signals between two or more individual devices (e.g., transistors, capacitors, or resistors).

As used herein, the term power line may refer to a line (i.e., metal line or interconnect) in the back-end-of-the-line (BEOL) of a semiconductor device used to distribute power (i.e., power and/or ground) between two or more individual devices (e.g., transistors, capacitors, or resistors).

As used herein, the terms “metal layer,” “metallization layer,” and “backside metal (BSM) layer” may be used interchangeably and may refer to one of a plurality of metal wiring levels in the BEOL of a semiconductor device. A metal layer may include a via formed in a first portion of a dielectric layer connected to a line formed in a second portion of the dielectric layer. For example, if a signal via formed in a first portion of a dielectric layer is connected to signal line formed in a second portion of the dielectric layer, the resulting signal via/line structure shall be said to be formed in the same metal layer. Similarly, if a power via formed in a first portion of a dielectric layer is connected to a power line formed in a second portion of the dielectric layer, the resulting power via/line structure shall be said to be formed in the same metal layer. Additionally, a metal layer may include a first row of signal lines formed in a bottom portion of a dielectric layer and a second row of signal lines formed in a top portion of the dielectric layer above the first row of signal lines. Here, the first set of signal lines and the second set of signal lines shall be said to be formed in the same metal layer.

The present invention will now be described in detail with reference to the FIGS. 1A . . . 1F-4A . . . 4F include various cross-sectional views depicting illustrative steps of methods for manufacturing semiconductor devices and the resulting semiconductor devices according to select embodiments of the present invention. One having ordinary skill in the art will appreciate that there are many options available for the formation of the structures described herein and that the following discussion does not limit embodiments to only the techniques described herein.

Referring now to FIGS. 1A-1F, FIG. 1A illustrates a cross-sectional view of an initial semiconductor structure, generally designated 100A, including a substrate 110 and a conductive metal layer 120, in accordance with at least one embodiment of the present invention. In assembly of semiconductor structure 100A, conductive metal layer 120 is formed on a top surface 112 of substrate 110.

In some embodiments, substrate 110 may include a front-end-of-the-line (FEOL) structure. A FEOL structure is typically present beneath the lowest level of the multilayered interconnect structure and includes a semiconductor substrate having one or more semiconductor devices such as, for example, transistors, capacitors, resistors, and etc. located thereon. In other embodiments, substrate 110 may include one or more interconnect levels of a multilayered interconnect structure, such as a back-end-of-the-line (BEOL) structure. A BEOL structure is typically where the individual semiconductor devices in the FEOL structure are interconnected with one another. In such embodiments, each interconnect level may include one or more electrically conductive structures embedded in an interconnect dielectric material. For example, the one or more interconnect levels of a multilayer interconnect structure may be formed from any generally known semiconductor materials, such as silicon, gallium arsenide, or germanium.

In some embodiments, and as depicted in FIG. 1A, substrate 110 is a bulk semiconductor wafer, such as a bulk silicon (Si), bulk germanium (Ge), bulk silicon germanium (SiGe) and/or bulk III-V semiconductor wafer. Alternatively, in other embodiments, substrate 110 is a semiconductor-on-insulator (SOI) wafer. A SOI wafter includes a SOI layer separated from a substrate by a buried insulator. When the buried insulator is an oxide, it is referred to herein as a buried oxide or BOX. The SOI layer can include any suitable semiconductor, such as Si, Ge, SiGe, and/or a III-V semiconductor.

Conductive metal layer 120 is formed by depositing a conductive metal material (e.g., via atomic layer deposition (ALD), chemical vapor deposition (CVD), plasma enhanced CVD (PECVD), or any other suitable deposition techniques) on top surface 112 of substrate 110. In an embodiment, the conductive metal material may be a metal or metal alloy including, but not limited to, copper (Cu), aluminum (Al), ruthenium (Ru), rhodium (Rh), iridium (Jr), tungsten (W), molybdenum (Mo), nickel (Ni), or an alloy thereof, such as, for example, a Cu—Al alloy.

FIG. 1B illustrates a cross-sectional view of semiconductor structure 100A depicted in FIG. 1A after performing subsequent processing steps, generally designated 100B, in accordance with at least one embodiment of the present invention. In assembly of semiconductor structure 100B, one or more subtractive etch processes are performed to etch through conductive metal layer 120 to form lines 121, 123, and lines 131, 133, 135, 137.

As depicted in FIG. 1B, lines 121, 123, and lines 131, 133, 135, 137 are formed following the patterning of conductive metal layer 120 using one or more subtractive etch processes. For example, a hard mask layer (not depicted) is formed by depositing a hard mask material (e.g., silicon nitride, titanium nitride, tantalum nitride, or any suitable metal-containing material) onto the top surface of conductive metal layer 120. The hard mask layer can be formed utilizing a deposition process including, but not limited to, CVD, PECVD, ALD, physical vapor deposition (PVD) or sputtering.

A photoresist material (not depicted) is then deposited onto the surface of the hard mask layer. The photoresist material can be applied by any suitable techniques, including, but not limited to, coating or spin-on techniques. A photomask (not depicted) patterned with shapes defining the top portion of lines 121, 123 to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the hard mask layer. Dry etch techniques (for example, an anisotropic etch process, such as reactive ion etch) may be employed to selectively remove portions of the hard mask layer to form the patterned hard mask. After formation of patterned hard mask, the photoresist material may be stripped from the patterned hard mask by ashing or other suitable processes. The resulting structure may be subjected to a wet clean.

The resulting patterned hard mask, which acts as an etch mask, is formed such that the portions of the underlying conductive metal layer 120 corresponding to the top portion of lines 121, 123 to be formed are protected by the patterned hard mask, while the remaining portions of the underlying conductive metal layer 120 are left exposed. During patterning of conductive metal layer 120 using the patterned hard mask, the physically exposed portions of conductive metal layer 120 are removed by an anisotropic etching process such as, for example, reactive ion etching (RIE), ion beam etching (IBE), chemical wet etching, or a combination of IBE and chemical wet etching. The etch removes the exposed portions of conductive metal layer 120 that are not protected by the patterned hard mask to form the top portion of lines 121, 123.

After forming the top portion of lines 121, 123, another patterned hard mask (not depicted) is formed on the exposed surfaces of conductive metal layer 120. The patterned hard mask may be formed using the same processes and materials for forming the top portion of lines 121, 123 as described above. The resulting patterned hard mask, which acts as an etch mask, is formed such that the portion of the underlying conductive metal layer 120 corresponding to the bottom portions of lines 121, 123, and lines 131, 133, 135, 137 to be formed are protected by the patterned hard mask, while the remaining portions of the underlying structure of conductive metal layer 120 are left exposed. The portions of conductive metal layer 120 left uncovered by the patterned hard mask are removed by an anisotropic etching process such as, for example, reactive ion etching (RIE), ion beam etching (IBE), chemical wet etching, or a combination of IBE and chemical wet etching. The etch removes the exposed portions of conductive metal layer 120 that are not protected by the patterned hard mask to form lines 121, 123, and lines 131, 133, 135, 137.

FIG. 1C illustrates a cross-sectional view of semiconductor structure 100B depicted in FIG. 1B after performing subsequent processing steps, generally designated 100C, in accordance with at least one embodiment of the present invention. In assembly of semiconductor structure 100C, a dielectric material is conformally deposited onto the patterned conductive metal layer 120 to form dielectric layer 150.

Dielectric layer 150 may be composed of an inorganic dielectric material or an organic dielectric material. In some embodiments, dielectric layer 150 may be porous. In other embodiments, dielectric layer 150 may be non-porous. In some embodiments, dielectric layer 150 may have a dielectric constant (all dielectric constants mentioned herein are measured relative to a vacuum, unless otherwise stated) that is about 4.0 or less. In an embodiment, dielectric layer 150 may have a dielectric constant of 2.8 or less. These dielectrics having a dielectric constant of 2.8 or less generally have a lower parasitic cross talk as compared to dielectric materials whose dielectric constant is greater than 4.0. Examples of suitable dielectric materials that may be employed as dielectric layer 150 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, 0 and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

A planarization process such as, for example, chemical mechanical planarization or polishing (CMP) and/or grinding, may subsequently be performed to remove portions of dielectric layer 150 present above a top surface 142 of lines 121, 123. The planarization stops at top surface 142 of lines 121, 123, such that a top surface 152 of dielectric layer 150 is substantially coplanar with top surface 142 of lines 121, 123.

As depicted by semiconductor structure 100C of FIG. 1C, lines 131, 133, 135, 137 form a first row of metal lines located in a bottom portion 104 of a metal layer 102 and between lines 121, 123. Lines 121, 123 are located in both bottom portion 104 and a top portion 106 of metal layer 102. A bottom surface 144 of lines 131, 133, 135, 137 is substantially coplanar with a bottom surface 146 of lines 121, 123, and a top surface 148 of lines 131, 133, 135, 137 is located below top surface 142 of lines 121, 123. Lines 131, 133, 135, 137 have a maximum critical dimension (CD) width and height that is less than the maximum CD width and height of lines 121, 123. Similarly, lines 131, 133, 135, 137 have a minimum CD width that is less than the minimum CD width of lines 121, 123.

FIG. 1D illustrates a cross-sectional view of semiconductor structure 100C depicted in FIG. 1C after performing subsequent processing steps, generally designated 100D, in accordance with at least one embodiment of the present invention. In assembly of semiconductor structure 100D, line openings 151, 153, 155 are formed following the patterning of dielectric layer 150 using a damascene process.

For example, the damascene process includes forming a patterned hard mask on top of dielectric layer 150. The patterned hard mask layer can be formed using the same processes and materials as described above with reference to FIG. 1B. The resulting patterned hard mask, which acts as an etch mask, is formed such that the portions of the underlying dielectric layer 150 corresponding to line openings 151, 153, 155 to be formed are left exposed, while the remaining portions of the underlying structure of dielectric layer 150 are protected by the patterned hard mask. During patterning of dielectric layer 150 using the patterned hard mask, the physically exposed portions of dielectric layer 150 are removed by an anisotropic etching process such as, for example, reactive ion etching (RIE), ion beam etching (IBE), chemical wet etching, or a combination of IBE and chemical wet etching. The etch removes the exposed portions of dielectric layer 150 that are not protected by the patterned hard mask to form line openings 151, 153, 155. The depth(s) of the line openings 151, 153, 155 can be controlled using a timed etching process.

As depicted by semiconductor structure 100D of FIG. 1D, line openings 151, 153, 155 are formed in top portion 106 of metal layer 102 and are horizontally staggered with respect to the first row of lines 131, 133, 135, 137 formed in bottom portion 104 of metal layer 102.

FIG. 1E illustrates a cross-sectional view of semiconductor structure 100D depicted in FIG. 1D after performing subsequent processing steps, generally designated 100E, in accordance with at least one embodiment of the present invention. In assembly of semiconductor structure 100E, after forming line openings 151, 153, 155 in top portion 106 of metal layer 102, via openings 157, 159 are formed in top portion 106 and bottom portion 104 of metal layer 102, respectively, using one or more damascene processes.

For example, another patterned hard mask (not depicted) is formed on the exposed surface of the patterned dielectric layer 150. The patterned hard mask may be formed using the same processes and materials as described above with reference to FIG. 1B. The resulting patterned hard mask, which acts as an etch mask, is formed such that the portions of the underlying dielectric layer 150 corresponding to via openings 157, 159 to be formed are left exposed, while the remaining portions of the underlying structure of dielectric layer 150 are protected by the patterned hard mask. The portions of dielectric layer 150 left uncovered by the patterned hard mask are removed by an anisotropic etching process such as, for example, reactive ion etching (RIE), ion beam etching (IBE), chemical wet etching, or a combination of IBE and chemical wet etching. The etch removes the exposed portions of dielectric layer 150 that are not protected by the patterned hard mask to form via openings 157, 159.

As depicted by semiconductor structure 100E of FIG. 1E, via opening 157 is formed above line 131, such that top surface 148 of line 131 is exposed. Via opening 159 is formed below line opening 155, such that top surface 112 of substrate 110 is exposed.

FIG. 1F illustrates a cross-sectional view of semiconductor structure 100E depicted in FIG. 1E after performing subsequent processing steps, generally designated 100F, in accordance with at least one embodiment of the present invention. In assembly of semiconductor structure 100F, a damascene process is performed, including the optional conformal deposition of a metal liner 160 on the exposed surfaces of the patterned dielectric layer 150, followed by the deposition of a conductive metal material to form conductive metal layer 170.

In some embodiments, and as depicted by semiconductor structure 100F, an optional metal liner 160 is conformally deposited on the exposed surfaces of the patterned dielectric layer 150. Metal liner 160 may include one or more thin layers of material such as, for example, tantalum (Ta), tantalum nitride (TaN), titanium nitride (TiN), cobalt (Co), ruthenium (Ru), tungsten (W), tungsten nitride (WN), titanium-tungsten (TiW), tungsten nitride (WN) manganese (Mn), manganese nitride (MnN) or other liner materials (or combinations of liner materials) such as RuTaN, Ta/TaN, CoWP, NiMoP, or NiMoB which are suitable for the given application. The thin metal liner serves as a barrier diffusion layer and adhesion layer. A conformal layer of metal liner 160 may be deposited using known techniques including, but not limited to, chemical vapor deposition (CVD), plasma enhanced chemical vapor deposition (PECVD), atomic layer deposition (ALD), physical vapor deposition (PVD), sputtering, chemical solution deposition or plating. The thickness of metal liner 160 may vary depending on the deposition process used, as well as the material employed. In some embodiments, metal liner 160 may have a thickness from 2 nm to 50 nm. However, other thicknesses that are less than 2 nm, or greater than 50 nm can also be employed in embodiments of the present invention.

In some embodiments, an optional plating seed layer (not depicted) can be formed on metal liner 160 as well. The optional plating seed layer is employed to selectively promote subsequent electroplating of a pre-selected conductive metal or metal alloy. The optional plating seed layer may be composed of Cu, a Cu alloy, Jr, an Jr alloy, Ru, a Ru alloy (e.g., TaRu alloy) or any other suitable noble metal or noble metal alloy having a low metal-plating overpotential. The optional plating seed layer can be formed by a conventional deposition process including, for example, CVD, PECVD, ALD, or PVD. The thickness of the optional plating seed layer may vary depending on the material of the optional plating seed layer, as well as the technique used in forming the same. Typically, the optional plating seed layer may have a thickness from 2 nm to 80 nm. However, other thicknesses that are less than 2 nm, and greater than 80 nm can also be employed in embodiments of the present invention.

Conductive metal layer 170 may be formed using the same processes and materials as described above with reference to FIG. 1A. In those embodiments in which a thin conformal copper (Cu) seed layer (not depicted) is deposited over the surface of metal liner 160 using, for example, PVD, conductive metal layer 170 may be subsequently formed by electroplating of Cu to fill line openings 151, 153, 155 (depicted in FIG. 1E), and via openings 157, 159 (depicted in FIG. 1E). In those embodiments in which metal liner 160 is not used, conductive metal layer 170 is formed by depositing the conductive metal material directly onto the exposed surfaces of the patterned dielectric layer 150.

Conductive metal layer 170 is formed such that line openings 151, 153, 155, and via openings 157, 159 (depicted in FIG. 1E) are filled with the conductive metal material. A planarization process such as, for example, chemical mechanical planarization or polishing (CMP) and/or grinding, may subsequently be performed to remove portions of conductive metal layer 170 located above top surface 152 of dielectric layer 150. The planarization stops at top surface 152 of dielectric layer 150, such that a top surface 162 of lines 171, 173, 175, and a top surface 164 of via 181 are substantially coplanar with top surface 152 of dielectric layer 150. In some embodiments, and as depicted by semiconductor structure 100F, the first row of lines 131, 133, 135, 137 and the second row of lines 171, 173, 175 are formed from different materials. In other embodiments, the first row of lines 131, 133, 135, 137 and the second row of lines 171, 173, 175 are formed from the same material(s).

As depicted by semiconductor structure 100F of FIG. 1F, lines 171, 173, 175 form a second row of metal lines located in top portion 106 of metal layer 102 that are horizontally staggered with respect to the first row of metal lines 131, 133, 135, 137 located in bottom portion 104 of metal layer 102. Top surface 162 of lines 171, 173, 175 is substantially coplanar with top surface 142 of metal lines 121, 123. In some embodiments, and as depicted by semiconductor structure 100F, a bottom surface 166 of the second row of lines 171, 173, 175 is located above top surface 148 of the first row of metal lines 131, 133, 135, 137. Similar to lines 131, 133, 135, 137, lines 171, 173, 175 have a maximum critical dimension (CD) width and height that is less than the maximum CD width and height of lines 121, 123.

As further depicted by semiconductor structure 100F of FIG. 1F, via 181 is formed above line 131, such that metal liner 160 is in contact with top surface 148 of line 131. In other words, metal liner 160 is located between the interface of line 131 and via 181. In other embodiments, metal liner 160 is not conformally deposited on the exposed surfaces of the patterned dielectric layer 150, such that conductive metal layer 170 is in contact with top surface 148 of line 131. In other words, no metal liner 160 is located between the interface of line 131 and via 181.

In some embodiments, and as depicted by semiconductor structure 100F, the first row of lines 131, 133, 135, 137 and the second row of lines 171, 173, 175 are signal lines, and lines 121, 123 are power lines. In some embodiments, and as depicted by semiconductor structure 100F, vias 181, 183 are signal vias.

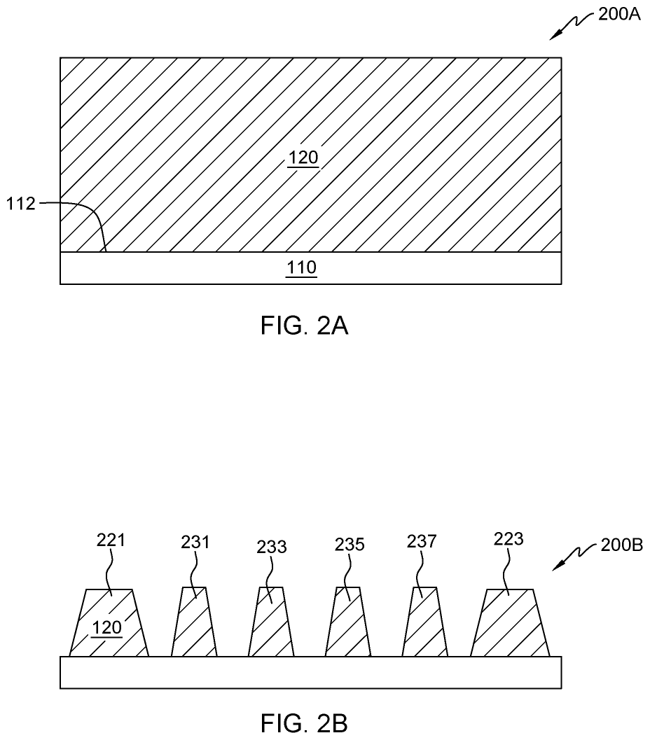

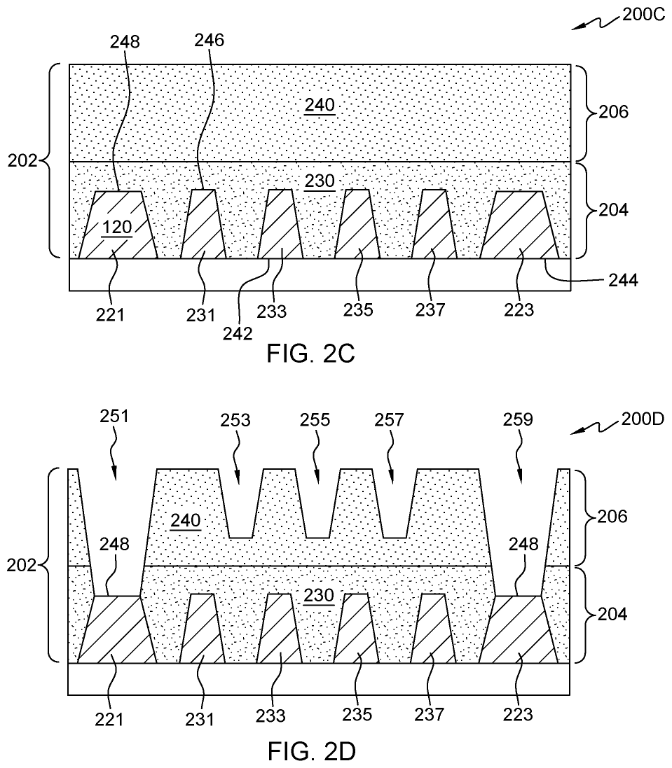

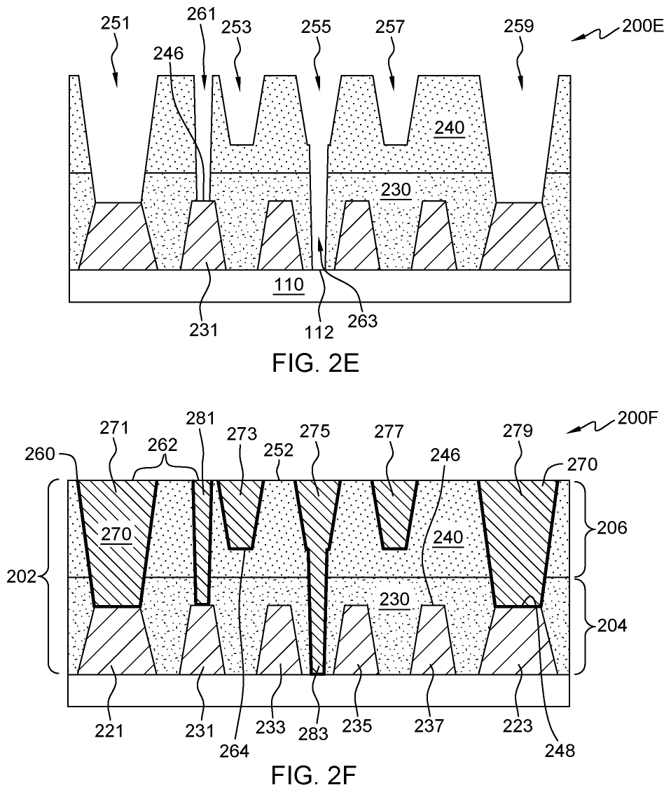

Referring now to FIGS. 2A-2F, FIG. 2A illustrates a cross-sectional view of an initial semiconductor structure, generally designated 200A, including substrate 110 and conductive metal layer 120, in accordance with at least one embodiment of the present invention. In assembly of semiconductor structure 200A, conductive metal layer 120 is formed on a top surface 112 of substrate 110. Substrate 110 and conductive metal layer 120 may be formed from the same processes and materials as described above with reference to FIG. 1A.

FIG. 2B illustrates a cross-sectional view of semiconductor structure 200A depicted in FIG. 2A after performing subsequent processing steps, generally designated 200B, in accordance with at least one embodiment of the present invention. In assembly of semiconductor structure 200B, one or more subtractive etch processes are performed to etch through conductive metal layer 120 to form lines 221, 223, and lines 231, 233, 235, 237.

As depicted in FIG. 2B, lines 221, 223, and lines 231, 233, 235, 237 are formed following the patterning of conductive metal layer 120 using one or more subtractive etch processes. For example, a patterned hard mask (not depicted) may be formed using the same processes and materials as described above with reference to FIG. 1B. The resulting patterned hard mask, which acts as an etch mask, is formed such that the portions of the underlying conductive metal layer 120 corresponding to lines 221, 223, and lines 231, 233, 235, 237 to be formed is left exposed, while the remaining portions of the underlying structure of conductive metal layer 120 are protected by the patterned hard mask. The portions of conductive metal layer 120 left uncovered by the patterned hard mask are removed by an anisotropic etching process such as, for example, reactive ion etching (RIE), ion beam etching (IBE), chemical wet etching, or a combination of IBE and chemical wet etching. The etch removes the exposed portions of conductive metal layer 120 that are not protected by the patterned hard mask to form lines 221, 223, and lines 231, 233, 235, 237.

FIG. 2C illustrates a cross-sectional view of semiconductor structure 200B depicted in FIG. 2B after performing subsequent processing steps, generally designated 200C, in accordance with at least one embodiment of the present invention. In assembly of semiconductor structure 200C, an optional capping material is conformally deposited on the exposed surfaces of the patterned conductive metal layer 120, followed by the deposition of a dielectric material.

In some embodiments, and as depicted by semiconductor structure 200C, an optional capping layer 230 is formed by conformally depositing a capping material on the exposed surfaces of the patterned conductive metal layer 120, followed by the formation of a dielectric layer 240. Capping layer 230 and dielectric layer 240 can be formed using deposition techniques including, but not necessarily limited to, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), spin-on coating, sputtering, and/or plating. Capping layer 230 can include, but is not limited to, silicon dioxides (SiO2), silicon nitrides (Si3N4), silicon carbides (SiC), nitrogen-hydrogen doped silicon carbides (SiC)(N,H), or any other insulators which are suitable for the given application. Dielectric layer 240 can include any of the dielectric materials as described above with reference to FIG. 1C. Capping layer 230 and dielectric layer 240 may have a thickness that is in the thickness range previously mentioned for dielectric layer 150. In those embodiments in which the optional capping layer 230 is not included, capping layer 230 may be replaced with a dielectric material, such as the same dielectric material used to form dielectric layer 240 or a different dielectric material than the dielectric material used to form dielectric layer 240.

As depicted by semiconductor structure 200C of FIG. 2C, lines 231, 233, 235, 237 form a first row of metal lines located in a bottom portion 204 of a metal layer 202 and between lines 221, 223 located in bottom portion 204 of metal layer 202. A bottom surface 242 of lines 231, 233, 235, 237 is substantially coplanar with a bottom surface 244 of lines 221, 223, and a top surface 246 of lines 231, 233, 235, 237 is substantially coplanar with a top surface 248 of lines 221, 223. Lines 231, 233, 235, 237 have a maximum critical dimension (CD) width and minimum CD width that is less than the maximum CD width and minimum CD width of lines 221, 223.

FIG. 2D illustrates a cross-sectional view of semiconductor structure 200C depicted in FIG. 2C after performing subsequent processing steps, generally designated 200D, in accordance with at least one embodiment of the present invention. In the exemplary assembly of semiconductor structure 200D, line openings 251, 253, 255, 257, 259 are formed following the patterning of optional capping layer 230 and dielectric layer 240 using one or more damascene processes.

For example, the one or more damascene processes includes forming a patterned hard mask on top of dielectric layer 240. The patterned hard mask layer can be formed using the same processes and materials as described above with reference to FIG. 1B. The resulting patterned hard mask, which acts as an etch mask, is formed such that the portions of the underlying capping layer 230 and dielectric layer 240 corresponding to line openings 251, 253, 255, 257, 259 to be formed are left exposed, while the remaining portions of the underlying structure of capping layer 230 and dielectric layer 240 are protected by the patterned hard mask. During patterning of capping layer 230 and dielectric layer 240 using the patterned hard mask, the physically exposed portions capping layer 230 and dielectric layer 240 are removed by an anisotropic etching process such as, for example, reactive ion etching (RIE), ion beam etching (IBE), chemical wet etching, or a combination of IBE and chemical wet etching. The etch removes the exposed portions capping layer 230 and dielectric layer 240 that are not protected by the patterned hard mask to form line openings 251, 253, 255, 257, 259. The depth(s) of the line openings 251, 253, 255, 257, 259 can be controlled using a timed etching process.

As depicted by semiconductor structure 200D of FIG. 2D, line openings 251, 253, 255, 257, 259 are formed in top portion 206 of metal layer 202. Line openings 251, 259 are formed in vertical alignment with lines 221, 223, such that top surface 248 of lines 221, 223 is exposed. Line openings 253, 255, 257 are horizontally staggered with respect to the first row of lines 231, 233, 235, 237.

FIG. 2E illustrates a cross-sectional view of semiconductor structure 200D depicted in FIG. 2D after performing subsequent processing steps, generally designated 200E, in accordance with at least one embodiment of the present invention. In assembly of semiconductor structure 200E, after forming line openings 251, 253, 255, 257, 259, one or more via openings are formed using one or more damascene processes.

For example, another patterned hard mask (not depicted) is formed on dielectric layer 240. The patterned hard mask may be formed using the same processes and materials as described above with reference to FIG. 1B. The resulting patterned hard mask, which acts as an etch mask, is formed such that the portions of the underlying capping layer 230 and dielectric layer 240 corresponding to via openings 261, 263 to be formed are left exposed, while the remaining portions of the underlying structure of capping layer 230 and dielectric layer 240 are protected by the patterned hard mask. The portions of capping layer 230 and dielectric layer 240 left uncovered by the patterned hard mask are removed by an anisotropic etching process such as, for example, reactive ion etching (RIE), ion beam etching (IBE), chemical wet etching, or a combination of IBE and chemical wet etching. The etch removes the exposed portions of capping layer 230 and dielectric layer 240 that are not protected by the patterned hard mask to form via openings 261, 263. The depth(s) of the via openings 261, 263 can be controlled using a timed etching process.

As depicted by semiconductor structure 200E of FIG. 2, via opening 261 is formed above line 231, such that top surface 246 of line 231 is exposed. Via opening 263 is formed below line opening 255, such that top surface 112 of substrate 110 is exposed.

FIG. 2F illustrates a cross-sectional view of semiconductor structure 200E depicted in FIG. 2E after performing subsequent processing steps, generally designated 200F, in accordance with at least one embodiment of the present invention. In assembly of semiconductor structure 200F, a damascene process is performed, including the optional conformal deposition of a metal liner 260 on the exposed surfaces of the patterned capping layer 230 and dielectric layer 240, followed by the deposition of a conductive metal material to form a conductive metal layer 270.

In some embodiments, and as depicted by semiconductor structure 200F, an optional metal liner 260 is conformally deposited on the exposed surfaces of the patterned capping layer 230 and dielectric layer 240. Metal liner 260 may be formed using the same processes and materials as described above with reference to FIG. 1C. The thickness of metal liner 260 may vary depending on the deposition process used, as well as the material employed, and may be similar to the thickness of metal liner 160 as described above with reference to FIG. 1C.

In some embodiments, an optional plating seed layer (not depicted) can be formed on metal liner 260 as well. The optional plating seed layer may be formed using the same processes and materials used to form the optional plating seed layer as described above with reference to FIG. 1F. The thickness of the optional plating seed layer may vary depending on the material of the optional plating seed layer, as well as the technique used in forming the same, and may be similar to the thickness of the optional plating seed layer as described above with reference to FIG. 1C.

Conductive metal layer 270 may be formed using the same processes and materials as described above with reference to FIG. 1A. In those embodiments in which a thin conformal copper (Cu) seed layer (not depicted) is deposited over the surface of metal liner 260 using, for example, PVD, conductive metal layer 270 may be subsequently formed by electroplating of Cu to fill line openings 251, 253, 255, 257, 259, and via openings 261, 263 (depicted in FIG. 2E). In those embodiments in which metal liner 260 is not used, conductive metal layer 270 is formed by depositing a conductive metal material directly onto the exposed surfaces of the patterned capping layer 230 and the patterned dielectric layer 240.

Conductive metal layer 270 is formed such that line openings 251, 253, 255, 257, 259, and via openings 261, 263 (depicted in FIG. 2E) are filled with the conductive metal material. A planarization process such as, for example, chemical mechanical planarization or polishing (CMP) and/or grinding, may subsequently be performed to remove portions of conductive metal layer 270 located above a top surface 252 of dielectric layer 240. The planarization stops at top surface 252 of dielectric layer 240, such that a top surface 262 of lines 271, 273, 275, 277, 279, and via 281 are substantially coplanar with top surface 252 of dielectric layer 240. In some embodiments, and as depicted by semiconductor structure 200F, the first row of lines 231, 233, 235, 237 and the second row of lines 273, 275, 277 are formed from different materials. In other embodiments, the first row of lines 231, 233, 235, 237 and the second row of lines 273, 275, 277 are formed from the same material(s).

As depicted by semiconductor structure 200F of FIG. 2F, lines 273, 275, 277 form a second row of metal lines located in top portion 206 of metal layer 202 that are horizontally staggered with respect to the first row of metal lines 231, 233, 235, 237 located in bottom portion 204 of metal layer 202. In some embodiments, and as depicted by semiconductor structure 200F, a bottom surface 264 of the second row of metal lines 273, 275, 277 is located above top surface 248 of the first row of metal lines 231, 233, 235, 237. Similar to lines 231, 233, 235, 247, lines 273, 275, 277 have a maximum critical dimension (CD) width and minimum CD width that is less than the maximum CD width and minimum CD width of lines 271, 279. Lines 273, 275, 277 also have a maximum CD height that is less than the maximum CD height of lines 271, 279.

As further depicted by semiconductor structure 200F of FIG. 2F, lines 271, 279 are formed in vertical alignment with lines 221, 223, such metal liner 260 of lines 271, 273 is in contact with top surface 248 of lines 221, 223. In other words, metal liner 260 is located between the interface of lines 221, 223 and line 271, 273, respectively. In other embodiments in which metal liner 260 is not conformally deposited on the exposed surfaces of the patterned capping layer and patterned dielectric layer 240, conductive metal layer 270 is in contact with top surface 248 of lines 221, 223. In other words, no metal liner 260 is located between the interface of lines 231, 233 and lines 271, 273, respectively.

As further depicted by semiconductor structure 200F of FIG. 2F, via 281 is formed above and in vertical alignment with line 231, such that metal liner 260 is in contact with top surface 246 of line 231. In other words, metal liner 260 is located between the interface of line 231 and via 281. In other embodiments in which metal liner 260 is not conformally deposited on the exposed surfaces of the patterned capping layer and patterned dielectric layer 240, conductive metal layer 270 is in contact with top surface 246 of line 231. In other words, no metal liner 260 is located between the interface of line 231 and via 281. In some embodiments, and as depicted in FIG. 200F, via 281 and line 231 are formed from different materials. In other embodiments, via 281 and line 231 are formed from the same material(s).

Via 283 is formed below and in vertical alignment with line 275. In some embodiments, and as depicted in FIG. 200F, metal liner 260 is not located between the interface of line 275 and via 283. In other embodiments, metal liner 260 is located between the interface of line 237 and via 283. In some embodiments, and as depicted in FIG. 200F, via 283 and line 275 are formed from the same material. In other embodiments, via 283 and line 275 are formed from different material(s).

In some embodiments, and as depicted by semiconductor structure 200F, the first row of metal lines 231, 233, 235, 237 and the second row of metal lines 273, 275, 277 are signal lines, and lines 221, 271 and lines 223, 279 form power lines, respectively. In some embodiments, and as depicted by semiconductor structure 200F, vias 281, 283 are signal vias.

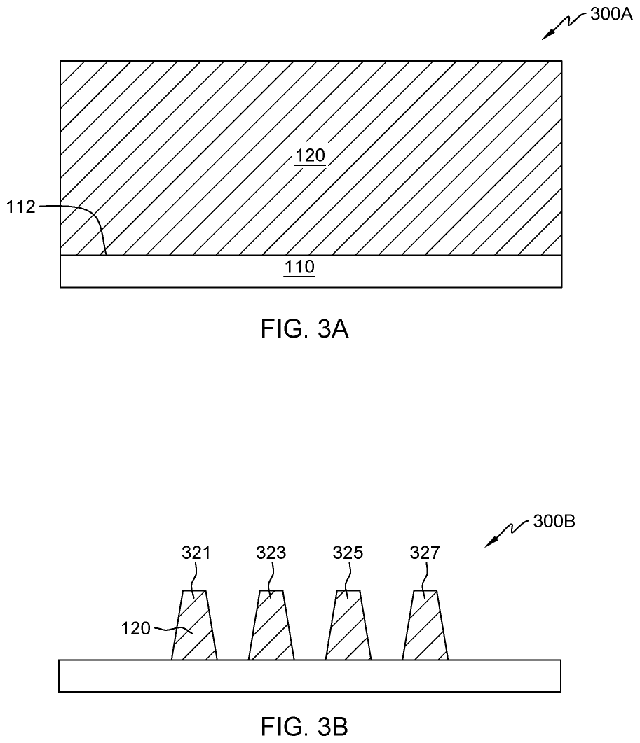

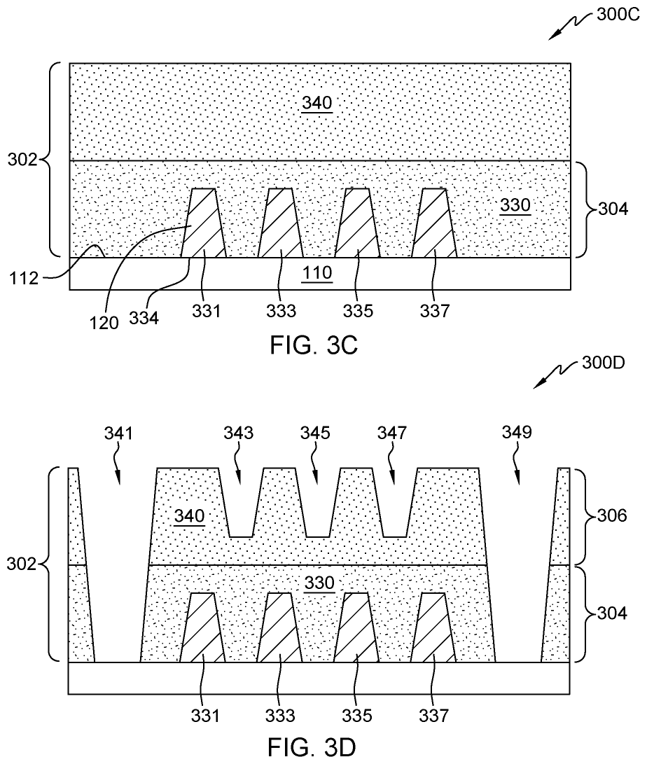

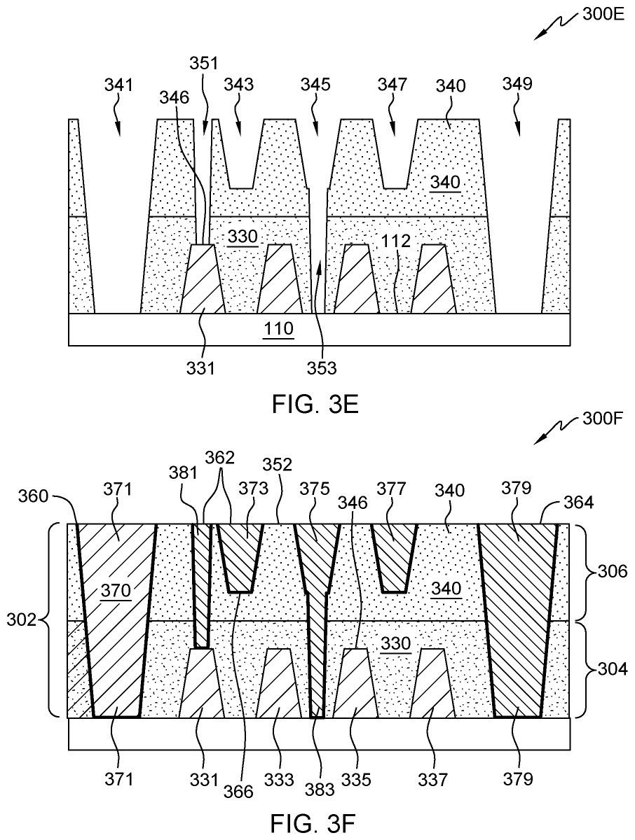

Referring now to FIG. 3A, FIG. 3A illustrates a cross-sectional view of an initial semiconductor structure, generally designated 300A, including substrate 110 and conductive metal layer 120, in accordance with at least one embodiment of the present invention. In assembly of semiconductor structure 300A, conductive metal layer 120 is formed on top surface 112 of semiconductor 110. Substrate 110 and conductive metal layer 120 may be formed from the same processes and materials as described above with reference to FIG. 1A.

FIG. 3B illustrates a cross-sectional view of semiconductor structure 300A depicted in FIG. 3A after performing subsequent processing steps, generally designated 300B, in accordance with at least one embodiment of the present invention. In assembly of semiconductor structure 300B, one or more subtractive etch processes are performed to etch through conductive metal layer 120 to form lines 321, 323, 325, 327.

As depicted in FIG. 3B, lines 321, 323, 325, 327 are formed following the patterning of conductive metal layer 120 using one or more subtractive etch processes. For example, a patterned hard mask (not depicted) may be formed using the same processes and materials as described above with reference to FIG. 1B. The resulting patterned hard mask, which acts as an etch mask, is formed such that the portions of the underlying conductive metal layer 120 corresponding to lines 321, 323, 325, and 327 to be formed are left exposed, while the remaining portions of the underlying structure of conductive metal layer 120 are protected by the patterned hard mask. The portions of conductive metal layer 120 left uncovered by the patterned hard mask are removed by an anisotropic etching process such as, for example, reactive ion etching (RIE), ion beam etching (IBE), chemical wet etching, or a combination of IBE and chemical wet etching. The etch removes the exposed portions of conductive metal layer 120 that are not protected by the patterned hard mask to form lines 321, 323, 325, 327.

FIG. 3C illustrates a cross-sectional view of semiconductor structure 300B depicted in FIG. 3B after performing subsequent processing steps, generally designated 300C, in accordance with at least one embodiment of the present invention. In assembly of semiconductor structure 300C, an optional capping material is deposited on the exposed surfaces of the patterned conductive metal layer 120, followed by the deposition of a dielectric material.

In some embodiments, and as depicted by semiconductor structure 300C, an optional capping layer 330 is formed by conformally depositing a capping material on the exposed surfaces of the patterned conductive metal layer 120, followed by the formation of a dielectric layer 340. Capping layer 330 and dielectric layer 340 can be formed using the same processes and materials as described above with reference to FIG. 2C. In those embodiments in which the optional capping layer 330 is not included, capping layer 330 may be replaced with a dielectric material, such as the same dielectric material used to form dielectric layer 340 or a different dielectric material than the dielectric material used to form dielectric layer 340.

As depicted by semiconductor structure 300C of FIG. 3C, lines 331, 333, 335, 337 form a first row of metal lines located in a bottom portion 304 of a metal layer 302. A bottom surface 334 of lines 331, 333, 335, 337 is substantially coplanar with a top surface 112 of semiconductor substrate 110.

FIG. 3D illustrates a cross-sectional view of semiconductor structure 300C depicted in FIG. 3C after performing subsequent processing steps, generally designated 300D, in accordance with at least one embodiment of the present invention. In assembly of semiconductor structure 300D, line openings 341, 343, 345, 347, 349 are formed following the patterning of capping layer 330 and dielectric layer 340 using a damascene process.

For example, the damascene process includes forming a patterned hard mask on top of dielectric layer 340. The patterned hard mask layer can be formed using the same processes and materials as described above with reference to FIG. 1B. The resulting patterned hard mask, which acts as an etch mask, is formed such that the portions of the underlying dielectric layer 340 and optional capping layer 330 corresponding to line openings 341, 343, 345, 347, 349 to be formed are left exposed, while the remaining portions of the underlying structure of dielectric layer 340 and the optional capping layer 330 are protected by the patterned hard mask. During patterning of capping layer 330 and dielectric layer 340 using the patterned hard mask, the physically exposed portions capping layer 330 and dielectric layer 340 are removed by an anisotropic etching process such as, for example, reactive ion etching (RIE), ion beam etching (IBE), chemical wet etching, or a combination of IBE and chemical wet etching. The etch removes the exposed portions capping layer 330 and dielectric layer 340 that are not protected by the patterned hard mask to form line openings 341, 343, 345, 347, 349. The depth(s) of line openings 341, 343, 345, 347, 349 can be controlled using a timed etching process.

As depicted by semiconductor structure 300D of FIG. 3D, line openings 341, 343, 345, 347, 349 are formed in both bottom portion 304 and top portion 306 of metal layer 302. Line openings 341, 343, 345, 347, 349 are formed in top portion 306 of metal layer 302. Line openings 343, 345, 347 are horizontally staggered with respect to the first row of lines 331, 333, 335, 337.

FIG. 3E illustrates a cross-sectional view of semiconductor structure 300D depicted in FIG. 3D after performing subsequent processing steps, generally designated 300E, in accordance with at least one embodiment of the present invention. In assembly of semiconductor structure 300E, after forming line openings 341, 343, 345, 347, 349, via openings 351, 353 are formed. For example, another patterned hard mask (not depicted) is formed on dielectric layer 340. The patterned hard mask may be formed using the same processes and materials as described above with reference to FIG. 1E. The resulting patterned hard mask, which acts as an etch mask, is formed such that the portions of the underlying capping layer 330 and dielectric layer 340 corresponding to via openings 351, 353 to be formed are left exposed, while the remaining portions of the underlying structure of capping layer 330 and dielectric layer 340 are protected by the patterned hard mask. The portions of capping layer 330 and dielectric layer 340 left uncovered by the patterned hard mask are removed by an anisotropic etching process such as, for example, reactive ion etching (RIE), ion beam etching (IBE), chemical wet etching, or a combination of IBE and chemical wet etching. The etch removes the exposed portions of capping layer 330 and dielectric layer 340 that are not protected by the patterned hard mask to form via openings 351, 353. The depth(s) of via openings 351, 353 can be controlled using a timed etching process.

As depicted by semiconductor structure 300E of FIG. 3E, via opening 351 is formed above line 331, such that top surface 346 of line 331 is exposed. Via opening 353 is formed below line opening 345, such that top surface 112 of substrate 110 is exposed.

FIG. 3F illustrates a cross-sectional view of semiconductor structure 300E depicted in FIG. 3E after performing subsequent processing steps, generally designated 300F, in accordance with at least one embodiment of the present invention. In assembly of semiconductor structure 300F, an optional metal liner 360 is conformally deposited on the exposed surfaces of the patterned capping layer 330 and patterned dielectric layer 340, followed by the deposition of a conductive metal material to form a conductive metal layer 370.

In some embodiments, and as depicted by semiconductor structure 300F, an optional metal liner 360 is conformally deposited on the exposed surfaces of the patterned capping layer 330 and dielectric layer 340. Metal liner 360 may be formed using the same processes and materials as described above with reference to FIG. 1C. The thickness of metal liner 360 may vary depending on the deposition process used, as well as the material employed, and may be similar to the thickness of metal liner 160 as described above with reference to FIG. 1C.

In some embodiments, an optional plating seed layer (not depicted) can be formed on metal liner 360 as well. The optional plating seed layer may be formed using the same processes and materials used to form the optional plating seed layer as described above with reference to FIG. 1F. The thickness of the optional plating seed layer may vary depending on the material of the optional plating seed layer, as well as the technique used in forming the same, and may be similar to the thickness of the optional plating seed layer as described above with reference to FIG. 1C.

Conductive metal layer 370 may be formed using the same processes and materials as described above with reference to FIG. 1A. In those embodiments in which a thin conformal copper (Cu) seed layer (not depicted) is deposited over the surface of metal liner 360 using, for example, PVD, conductive metal layer 370 may be subsequently formed by electroplating of Cu to fill line openings 341, 343, 345, 347, 349 and via openings 351, 353 (depicted in FIG. 3E). In those embodiments in which metal liner 360 is not used, conductive metal layer 370 is formed by depositing a conductive metal material directly onto the exposed surfaces of the patterned capping layer 330 and the patterned dielectric layer 340.

Conductive metal layer 370 is formed such that line openings 341, 343, 345, 347, 349, and via openings 351, 353 (depicted in FIG. 3E) are filled with the conductive metal material. A planarization process such as, for example, chemical mechanical planarization or polishing (CMP) and/or grinding, may subsequently be performed to remove portions of conductive metal layer 370 located above top surface 352 of dielectric layer 340. The planarization stops at top surface 352 of dielectric layer 340, such that a top surface 362 of lines 371, 373, 375, 377, 379, and via 381 are substantially coplanar with top surface 352 of dielectric layer 340. In some embodiments, and as depicted by semiconductor structure 300F, the first row of metal lines 331, 333, 335, 337 and the second row of metals lines 373, 375, 377 are formed from different material(s). In other embodiments, the first row of metal lines 331, 333, 335, 337 and the second row of metal lines 373, 375, 377 are formed from the same material(s).

As depicted by semiconductor structure 300F of FIG. 3F, lines 373, 375, 377 form a second row of metal lines located in top portion 306 of metal layer 302 that are horizontally staggered with respect to the first row of lines 331, 333, 335, 337 located in bottom portion 304 of metal layer 302. Top surface 362 of lines 373, 375, 377 is substantially coplanar with top surface 364 of lines 371, 379. In some embodiments, and as depicted by semiconductor structure 300F, a bottom surface 366 of the second row of lines 373, 375, 377 is located above top surface 346 of the first row of lines 331, 333, 335, 337. Similar to lines 231, 233, 235, 237, lines 373, 375, 377 have a maximum critical dimension (CD) width and minimum CD width that is less than the maximum CD width and minimum CD width of lines 371, 379. Lines 373, 375, 377 also have a maximum CD height that is less than the maximum CD height of lines 371, 379.

As further depicted by semiconductor structure 300F of FIG. 3F, via 381 is formed above and in vertical alignment with line 331, such that metal liner 360 is in contact with top surface 346 of line 331. In other words, metal liner 360 is located between the interface of line 331 and via 381. In other embodiments in which metal liner 360 is not conformally deposited on the exposed surfaces of the patterned capping layer and patterned dielectric layer 340, conductive metal layer 370 is in contact with top surface 346 of line 331. In other words, no metal liner 360 is located between the interface of line 331 and via 381. In some embodiments, and as depicted in FIG. 300F, via 381 and line 331 are formed from the same material(s). In other embodiments, via 381 and line 331 are formed from different material(s).

Via 383 is formed below and in vertical alignment with line 375. In some embodiments, and as depicted in FIG. 300F, metal liner 360 is not located between the interface of line 375 and via 383. In other embodiments, metal liner 360 is located between the interface of line 337 and via 383. In some embodiments, and as depicted in FIG. 300F, via 383 and line 375 are formed from the same material(s). In other embodiments, via 383 and line 375 are formed from different material(s).

In some embodiments, and as depicted by semiconductor structure 300F, the first row of lines 331, 333, 335, 337 and the second row of lines 373, 375, 377 are signal lines, and lines 371, 379 are power lines. In some embodiments, and as depicted by semiconductor structure 300F, vias 381, 383 are signal vias.

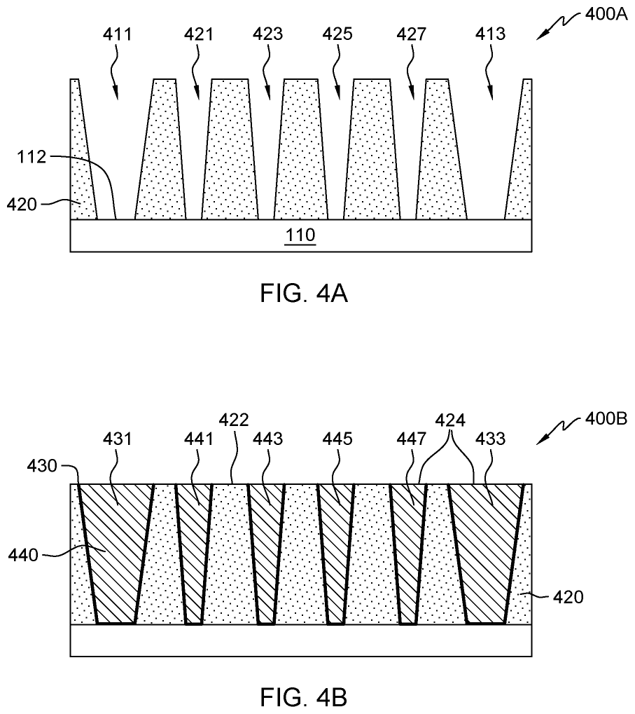

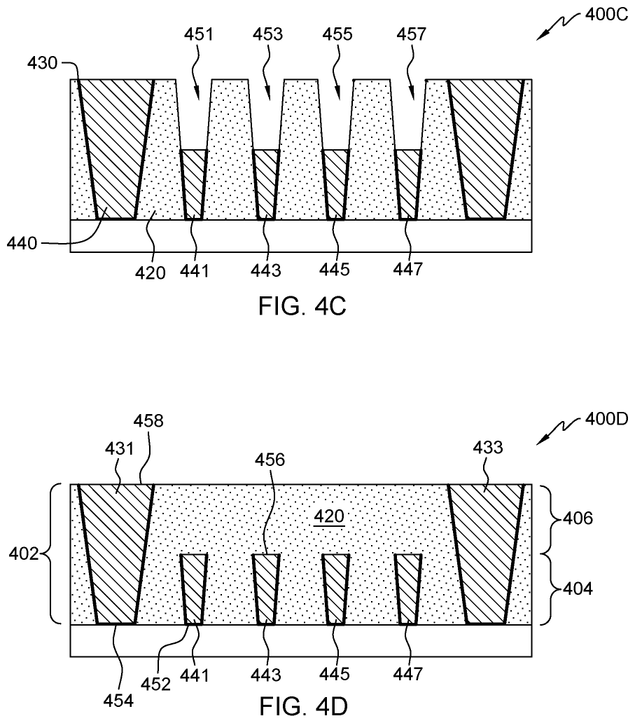

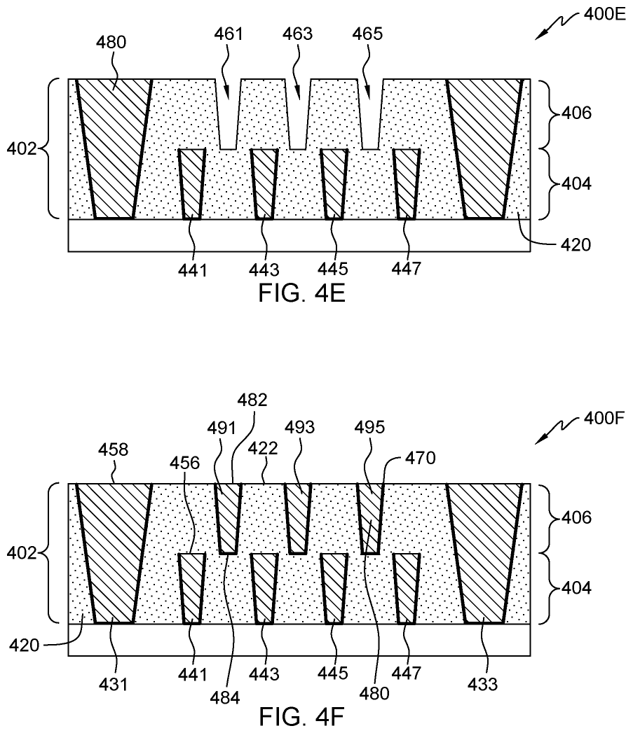

Referring now to FIG. 4A, FIG. 4A illustrates a cross-sectional view of an initial semiconductor structure, generally designated 400A, including substrate 110, dielectric layer 420, and line openings 411, 413, and line openings 421, 423, 425, 427, in accordance with at least one embodiment of the present invention. In assembly of semiconductor structure 400A, dielectric layer 420 is initially formed on top surface 112 of substrate 110. Substrate 110 and dielectric layer 420 may be formed from the same processes and materials as described above with reference to FIGS. 1A and 1C.

Following the arrangement of dielectric layer 420 on substrate 110, line openings 411, 413, and line openings 421, 423, 425, 427 are formed in the dielectric layer 420 using one or more damascene processes. For example, a patterned hard mask (not depicted) may be formed using the same processes and materials as described above with reference to FIG. 1D. The resulting patterned hard mask, which acts as an etch mask, is formed such that the portions of the underlying dielectric layer 420 corresponding to line openings 411, 413 and line openings 421, 423, 425, 427 to be formed is left exposed, while the remaining portions of the underlying structure of dielectric layer 420 are protected by the patterned hard mask. The portions of dielectric layer 420 left uncovered by the patterned hard mask are removed by an anisotropic etching process such as, for example, reactive ion etching (RIE), ion beam etching (IBE), chemical wet etching, or a combination of IBE and chemical wet etching. The etch removes the exposed portions of dielectric layer 420 that are not protected by the patterned hard mask to form line openings 411, 413 and line openings 421, 423, 425, 427.

FIG. 4B illustrates a cross-sectional view of semiconductor structure 400A depicted in FIG. 4A after performing subsequent processing steps, generally designated 400B, in accordance with at least one embodiment of the present invention. In assembly of semiconductor structure 400B, an optional metal liner 430 is conformally deposited on the exposed surfaces of the patterned dielectric layer 420, followed by the deposition of a conductive metal material to form conductive metal layer 440.

In some embodiments, and as depicted by semiconductor structure 200F, an optional metal liner 430 is conformally deposited on the exposed surfaces of the patterned dielectric layer 420. Metal liner 430 may be formed using the same processes and materials as described above with reference to FIG. 1C. The thickness of metal liner 430 may vary depending on the deposition process used, as well as the material employed, and may be similar to the thickness of metal liner 160 as described above with reference to FIG. 1C.

In some embodiments, an optional plating seed layer (not depicted) can be formed on metal liner 430 as well. The optional plating seed layer may be formed using the same processes and materials used to form the optional plating seed layer as described above with reference to FIG. 1F. The thickness of the optional plating seed layer may vary depending on the material of the optional plating seed layer, as well as the technique used in forming the same, and may be similar to the thickness of the optional plating seed layer as described above with reference to FIG. 1C.

Conductive metal layer 440 may be formed using the same processes and materials as described above with reference to FIG. 1A. In those embodiments in which a thin conformal copper (Cu) seed layer (not depicted) is deposited over the surface of metal liner 430 using, for example, PVD, conductive metal layer 440 may be subsequently formed by electroplating of Cu to fill line openings 411, 413 and line openings 421, 423, 425, 427 (depicted in FIG. 4A). In those embodiments in which metal liner 430 is not used, conductive metal layer 440 is formed by depositing a conductive metal material directly onto the exposed surfaces of the patterned dielectric layer 420.

Conductive metal layer 440 is formed such that line openings 411, 413 and line openings 421, 423, 425, 427 (depicted in FIG. 4A) are filled with the conductive metal material. A planarization process such as, for example, chemical mechanical planarization or polishing (CMP) and/or grinding, may subsequently be performed to remove portions of conductive metal layer 440 located above top surface 422 of dielectric layer 420. The planarization stops at top surface 422 of dielectric layer 420, such that a top surface 424 of lines 431, 433 and lines 441, 443, 445, 447 are substantially coplanar with top surface 422 of dielectric layer 420.

FIG. 4C illustrates a cross-sectional view of semiconductor structure 400B depicted in FIG. 4B after performing subsequent processing steps, generally designated 400C, in accordance with at least one embodiment of the present invention. In assembly of semiconductor structure 400C, lines 441, 443, 445, 447 are partially recessed to form openings 451, 453, 455, 457 using a subtractive etch removal process.

Lines 441, 443, 445, 447 may be partially recessed to form openings 451, 453, 455, 457 using the same subtractive etching process and materials as described above with reference to FIG. 1B. For example, a patterned hard mask (not depicted) may be formed using the same processes and materials as described above with reference to FIG. 1B. The resulting patterned hard mask, which acts as an etch mask, is formed such that the portions of the underlying optional metal liner 430 and conductive metal layer 440 corresponding to openings 451, 453, 455, 457 to be formed are left exposed, while the remaining portions of the underlying structure of dielectric layer 420, optional metal liner 430, and conductive metal layer 440 are protected by the patterned hard mask. The portions of the optional metal liner 430 and conductive metal layer 440 left uncovered by the patterned hard mask are removed by an anisotropic etching process such as, for example, reactive ion etching (RIE), ion beam etching (IBE), chemical wet etching, or a combination of IBE and chemical wet etching. The etch removes the exposed portions of the optional metal liner 430 and conductive metal layer 440 that are not protected by the patterned hard mask to form openings 451, 453, 455, 457.

FIG. 4D illustrates a cross-sectional view of semiconductor structure 400C depicted in FIG. 4C after performing subsequent processing steps, generally designated 400D, in accordance with at least one embodiment of the present invention. In assembly of semiconductor structure 400D, a dielectric material is deposited onto the patterned dielectric layer 420 until line openings 451, 453, 455, 457 (depicted in FIG. 4C) are filled with the dielectric material.

The dielectric material can be deposited using deposition techniques including, but not necessarily limited to, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), spin-on coating, sputtering, and/or plating. The dielectric material can include any of the dielectric materials as described above with reference to FIG. 1C.

As depicted by semiconductor structure 400D of FIG. 4D, lines 441, 443, 445, 447 form a first row of metal lines located in a bottom portion 404 of metal layer 402 and between lines 431, 433. A bottom surface 452 of lines 441, 443, 445, 447 is substantially coplanar with a bottom surface 454 of lines 431, 433, and a top surface 456 of lines 441, 443, 445, 447 is below a top surface 458 of lines 431, 433. Lines 441, 443, 445, 447 have a maximum critical dimension (CD) width and minimum CD width that is less than the maximum CD width and minimum CD width of lines 431, 433.

FIG. 4E illustrates a cross-sectional view of semiconductor structure 400D depicted in FIG. 4D after performing subsequent processing steps, generally designated 400E, in accordance with at least one embodiment of the present invention. In assembly of semiconductor structure 400E, line openings 461, 463, 465 are formed following the patterning of dielectric layer 420 using one or more damascene processes.

For example, the one or more damascene processes includes forming a patterned hard mask on top of dielectric layer 420. The patterned hard mask layer can be formed using the same processes and materials as described above with reference to FIG. 1B. The resulting patterned hard mask, which acts as an etch mask, is formed such that the portions of the underlying dielectric layer 420 corresponding to line openings 461, 463, 465 to be formed are left exposed, while the remaining portions of the underlying structure of dielectric layer 420 are protected by the patterned hard mask. During patterning of dielectric layer 420 using the patterned hard mask, the physically exposed portions of dielectric layer 420 are removed by an anisotropic etching process such as, for example, reactive ion etching (RIE), ion beam etching (IBE), chemical wet etching, or a combination of IBE and chemical wet etching. The etch removes the exposed portions of dielectric layer 420 that are not protected by the patterned hard mask to form line openings 461, 463, 465. The depth(s) of the line openings 461, 463, 465 can be controlled using a timed etching process.

As depicted by semiconductor structure 400E of FIG. 4E, line openings 461, 463, 465 are formed in top portion 406 of metal layer 402 and are horizontally staggered with respect to the first row of lines 441, 443, 445, 447.

FIG. 4F illustrates a cross-sectional view of semiconductor structure 400E depicted in FIG. 4E after performing subsequent processing steps, generally designated 400F, in accordance with at least one embodiment of the present invention. In assembly of semiconductor structure 400F, a damascene process is performed, including the optional conformal deposition of a metal liner 470 on the exposed surfaces of the patterned dielectric layer 420, followed by the deposition of a conductive metal material to form a conductive metal layer 480.

In some embodiments, and as depicted by semiconductor structure 400F, an optional metal liner 470 is conformally deposited on the exposed surfaces of the patterned dielectric layer 420. Metal liner 470 may be formed using the same processes and materials as described above with reference to FIG. 1C. The thickness of metal liner 470 may vary depending on the deposition process used, as well as the material employed, and may be similar to the thickness of metal liner 160 as described above with reference to FIG. 1C.

In some embodiments, an optional plating seed layer (not depicted) can be formed on metal liner 470 as well. The optional plating seed layer may be formed using the same processes and materials used to form the optional plating seed layer as described above with reference to FIG. 1F. The thickness of the optional plating seed layer may vary depending on the material of the optional plating seed layer, as well as the technique used in forming the same, and may be similar to the thickness of the optional plating seed layer as described above with reference to FIG. 1C.

Conductive metal layer 480 may be formed using the same processes and materials as described above with reference to FIG. 1A. In those embodiments in which a thin conformal copper (Cu) seed layer (not depicted) is deposited over the surface of metal liner 480 using, for example, PVD, conductive metal layer 480 may be subsequently formed by electroplating of Cu to fill line openings 461, 463, 465 (depicted in FIG. 4E). In those embodiments in which metal liner 470 is not used, conductive metal layer 480 is formed by depositing a conductive metal material directly onto the exposed surfaces of the patterned dielectric layer 420.

Conductive metal layer 480 is formed such that line openings 461, 463, 465 (depicted in FIG. 4E) are filled with the conductive metal material. A planarization process such as, for example, chemical mechanical planarization or polishing (CMP) and/or grinding, may subsequently be performed to remove portions of conductive metal layer 480 located above top surface 422 of dielectric layer 420. The planarization stops at top surface 422 of dielectric layer 420, such that a top surface 482 of lines 491, 493, 495 is substantially coplanar with top surface 422 of dielectric layer 420. In some embodiments, and as depicted by semiconductor structure 400F, the first row of metal lines 441, 443, 445, 447 and the second row of metal lines 491, 493, 495 are formed from the same material(s). In other embodiments, the first row of metal lines 441, 443, 445, 447 and the second row of metal lines 491, 493, 495 are formed from different material(s).

As depicted by semiconductor structure 400F of FIG. 4F, lines 491, 493, 495 form a second row of metal lines located in top portion 406 of metal layer 402 that are horizontally staggered with respect to the first row of lines 441, 443, 445, 447 located in bottom portion 404 of metal layer 402. Top surface 482 of lines 491, 493, 495 is substantially coplanar with top surface 458 of lines 431, 433. In some embodiments, and as depicted by semiconductor structure 400F, a bottom surface 484 of the second row of metal lines 491, 493, 495 is located above top surface 456 of the first row of metal lines 441, 443, 445, 447. Similar to lines 441, 443, 445, 447, lines 491, 493, 495 have a maximum critical dimension (CD) width (W₁) and minimum CD width (W₂) that is less than the maximum CD width and minimum CD width of lines 431, 433. Lines 491, 493, 495 also have a maximum CD height that is less than the maximum CD height of lines 431, 433.

In some embodiments, and as depicted by semiconductor structure 400F, the first row of metal lines 441, 443, 445, 447 and the second row of metal lines 491, 493, 495 are signal lines, and lines 431, 433 are power lines.

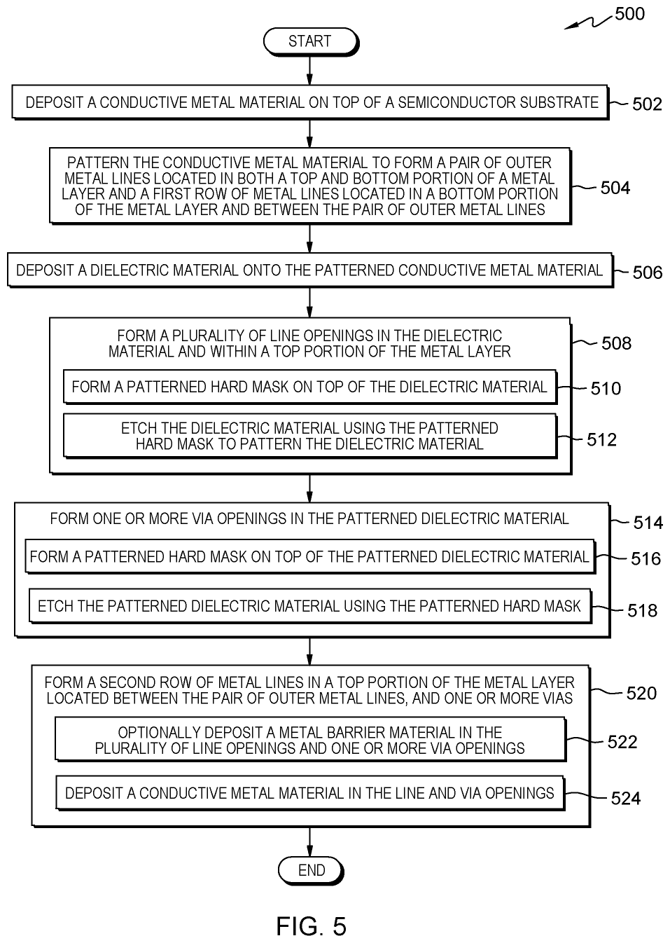

FIGS. 5-8, generally designated 500, 600, 700, and 800, respectfully are methods of fabricating semiconductor interconnect structures corresponding to the semiconductor structures described with reference to FIGS. 1A-1F . . . 4A-4F, and accordingly, The method may be used in conjunction with, for example, any of the exemplary fabrication sequences of FIGS. 1A-1F . . . 4A-4F.

Referring now to FIG. 5, the method 500 optionally begins at block 502, where a conductive metal material is deposited on top of a semiconductor substrate. At block 504, the conductive metal material is patterned using one or more subtractive etch processes to form a pair of outer metal lines and a first row of inner metal lines located between the pair of outer metal lines.

In some embodiments, the pair of outer metal lines are located in both a bottom portion of a metal layer and a top portion of the metal layer, and the first row of inner metal lines are located in the bottom portion of the metal layer. In those embodiments in which the pair of outer metal lines are located in both the bottom and top portion of the metal layer, the first row of inner metal lines are shorter than the pair of outer metal lines. In some embodiments, the first row of inner metal lines are narrower than the pair of outer metal lines.

At block 506, a dielectric material is conformally deposited onto the patterned conductive metal layer. At block 508, a plurality of line openings are formed in a top portion of the dielectric material. In some embodiments, forming the plurality of line openings comprises (at block 510) forming a patterned hard mask on top of the dielectric material, and etching (at block 512) the respective portions of the dielectric material exposed by the patterned hard mask to form a patterned dielectric layer including the plurality of line openings. In some embodiments, the one or more line openings located in the top portion of the metal layer are horizontally staggered with respect to the first row of inner metal lines located within the bottom portion of the metal layer. In other embodiments, the one or more line openings located in the top portion of the metal layer are vertically aligned with respect to the first row of inner metal lines located in the bottom portion of the metal layer.

At block 514, one or more via openings are formed in the dielectric material. In those embodiments in which the plurality of line openings located in the top portion of the metal layer are horizontally staggered with respect to the first row of inner metal lines located in the bottom portion of the metal layer, forming the one or more via openings in the dielectric layer comprises (at optional block 516) forming a patterned hard mask on top of the patterned dielectric material, and etching (at block 518) the respective portion(s) of the patterned dielectric material exposed by the patterned hard mask to form the one or more via openings. In some embodiments, a via opening is formed above a metal line of the first row of inner metal lines, such that a top surface of the metal line is exposed. In some embodiments, a via opening is formed below a line opening formed in the top portion of the metal layer, such that the via opening extends from the line opening.

At block 520, one or more via openings and a second row of metal lines located in the top portion of the metal layer and one or more vias are formed. In some embodiments, forming the second row of metal lines located in the top portion of the metal layer and the one or more vias comprises optionally conformally depositing (at block 522) a metal barrier material in the one plurality of line openings located in the top portion of the metal layer and the one or more vias openings to form a metal barrier, and depositing (at block 524) a conductive metal material in the via and line openings. In some embodiments, a via is formed in the top portion of the metal layer, such that the via is in contact with a metal line of the first row of inner metal lines formed in the bottom portion of the metal layer. In some embodiments, a via is formed in the bottom portion of the metal layer, such that the via is in contact with a metal line of the second row of inner metal lines located in the top portion of the metal layer.

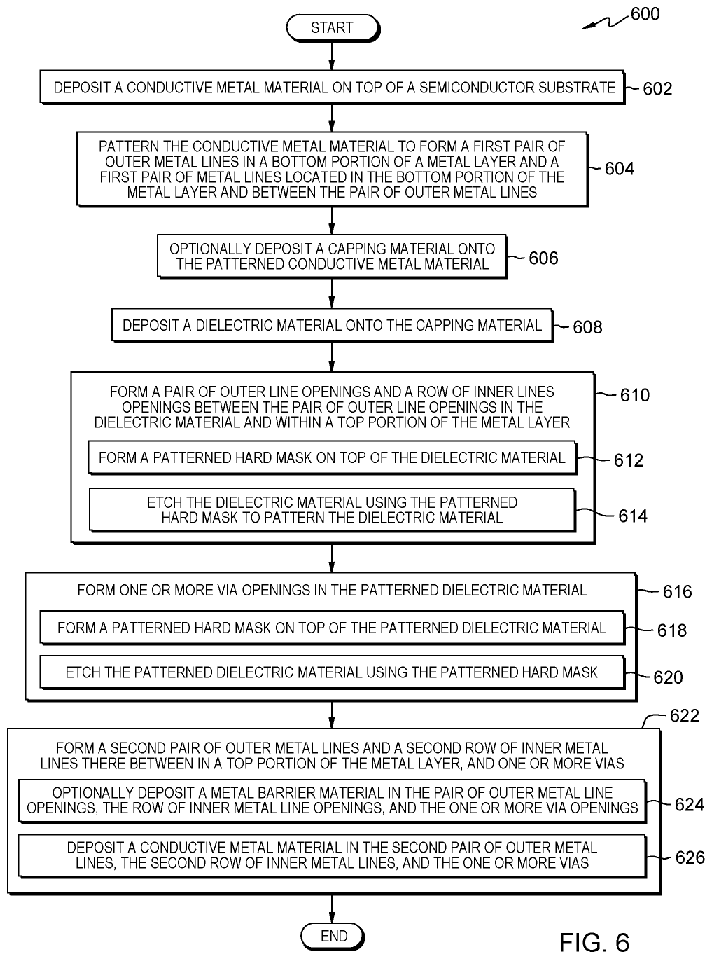

Referring now to FIG. 6, the method 600 optionally begins at block 602, where a conductive metal layer is formed on top of a semiconductor substrate. At block 604, the conductive metal layer is patterned using one or more subtractive etch processes to form a first pair of outer metal lines and a first row of inner metal lines located between the first pair of outer metal lines.

In some embodiments, the first pair of outer metal lines and the first row of inner metal lines are located in a bottom portion of a metal layer. In those embodiments in which the first pair of metal lines are located in the bottom portion of the metal layer and the first row of metal lines are located in the bottom portion of the metal layer, the first row of inner metal lines and the pair of outer metal lines are equal in height. In some embodiments, the first row of inner metal lines are narrower than the first pair of outer metal lines.

At optional block 606, a capping material is conformally deposited onto the patterned conductive metal layer to form a capping layer, followed by the deposition of a dielectric material to form a dielectric layer at block 608.

At block 610, a pair of outer line openings and a plurality of inner line openings located between the pair of outer line openings are formed. In some embodiments, forming the pair of outer line openings and the plurality of inner line openings comprises (at block 612) forming a patterned hard mask on top of the dielectric layer, and etching (at block 614) the respective portions of the dielectric layer exposed by the patterned hard mask to form a patterned dielectric layer including the pair of outer line openings and the plurality of inner line openings. In some embodiments, the second pair of outer line openings are vertically aligned with first pair of outer line openings located in the bottom portion of the metal layer and extend entirely through the dielectric layer and partially through the capping layer, such that a top surface of the first pair of outer metal lines is exposed. In some embodiments, the plurality of line openings located in the top portion of the metal layer are horizontally staggered with respect to the first row of inner metal lines located within the bottom portion of the metal layer. In other embodiments, the plurality of line openings located in the top portion of the metal layer are vertically aligned with respect to the first row of inner metal lines located in the bottom portion of the metal layer.

At block 616, one or more via openings are formed in the metal layer. In those embodiments in which the plurality of line openings located in the top portion of the metal layer are horizontally staggered with respect to the first row of inner metal lines located in the bottom portion of the metal layer, forming the one or more via openings in the metal layer comprises (at optional block 618) forming a patterned hard mask on top of the patterned dielectric layer, and etching (at block 620) the respective portion(s) of the patterned dielectric layer exposed by the patterned hard mask to form the one or more via openings. In some embodiments, a via opening is formed above a metal line of the first row of inner metal lines, such that a top surface of the metal line is exposed. In some embodiments, a via opening is formed below a line opening formed in the top portion of the metal layer, such that the via opening extends from the bottom of the line opening.

At block 622, a second row of metal lines located in the top portion of the metal layer and one or more vias are formed. In some embodiments, forming the second row of metal lines located in the top portion of the metal layer and the one or more vias comprises optionally conformally depositing (at block 624) a metal barrier material in the one plurality of line openings located in the top portion of the metal layer and the one or more vias to form a metal barrier, and depositing (at block 626) a conductive metal material in the via and line openings. In some embodiments, a via is formed in the top portion of the metal layer, such that the via is in contact with a metal line of the first row of inner metal lines formed in the bottom portion of the metal layer. In some embodiments, a via is formed in the bottom portion of the metal layer, such that the via is in contact with a metal line of the second row of inner metal lines located in the top portion of the metal layer.

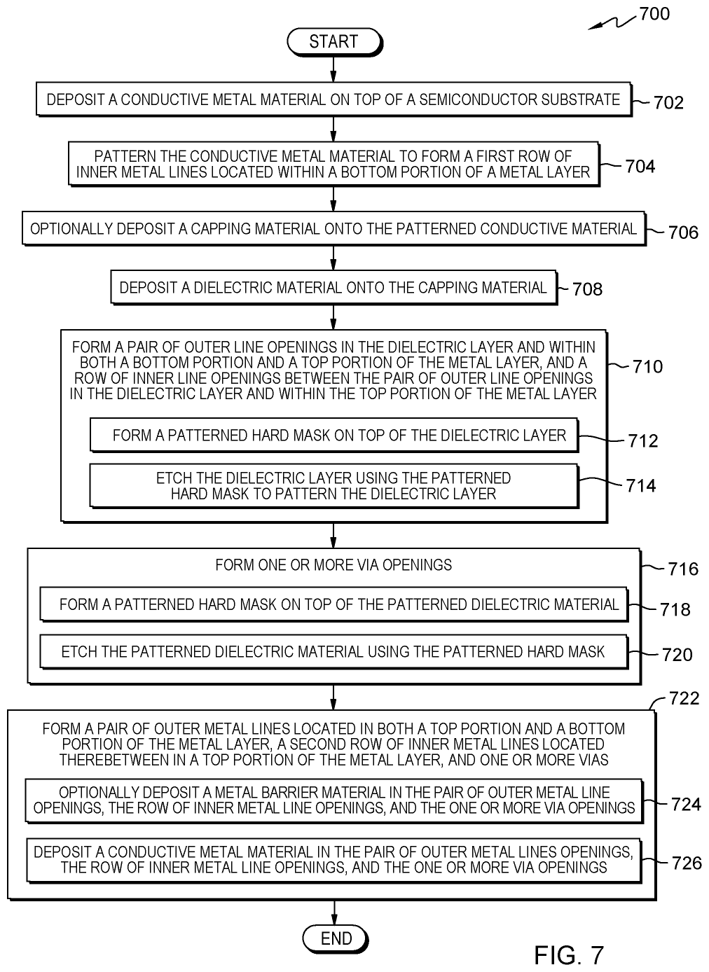

Referring now to FIG. 7, the method 700 optionally begins at block 702, where a conductive metal layer is formed on top of a semiconductor substrate. At block 704, the conductive metal layer is patterned using one or more subtractive etch processes to form a first row of inner metal lines. In some embodiments, the first row of inner metal lines are located in a bottom portion of a metal layer.

At optional block 706, a capping material is conformally deposited onto the patterned conductive metal layer to form a capping layer, followed by the deposition of a dielectric material to form a dielectric layer at block 708.

At block 710, a pair of outer line openings and a plurality of inner line openings located between the pair of outer line openings are formed. In some embodiments, forming the pair of outer line openings and the plurality of inner line openings comprises (at block 712) forming a patterned hard mask on top of the dielectric layer, and etching (at block 714) the respective portions of the dielectric layer exposed by the patterned hard mask to form a patterned dielectric layer including the pair of outer line openings and the plurality of inner line openings. In some embodiments, the pair of outer line openings extend entirely through both the dielectric layer and the capping layer (i.e., through the entire metal layer) and are located in both the bottom portion and a top portion of the metal layer. In some embodiments, the plurality of line openings extend partially through the dielectric layer and are located in the top portion of the metal layer. In some embodiments, the plurality of line openings located in the top portion of the metal layer are horizontally staggered with respect to the first row of inner metal lines located within the bottom portion of the metal layer. In other embodiments, the plurality of line openings located in the top portion of the metal layer are vertically aligned with respect to the first row of inner metal lines located in the bottom portion of the metal layer.

At block 716, one or more via openings are formed in the metal layer. In those embodiments in which the plurality of line openings located in the top portion of the metal layer are horizontally staggered with respect to the first row of inner metal lines located in the bottom portion of the metal layer, forming the one or more via openings in the metal layer comprises (at optional block 718) forming a patterned hard mask on top of the patterned dielectric layer, and etching (at block 720) the respective portion(s) of the patterned dielectric layer exposed by the patterned hard mask to form the one or more via openings. In some embodiments, a via opening is formed above a metal line of the first row of inner metal lines, in which the via opening extends entirely through the dielectric layer and partially through the capping layer such that a top surface of the metal line is exposed. In some embodiments, a via opening is formed below a line opening formed in the top portion of the metal layer, in which the via opening extends partially through the dielectric layer from the bottom of the line opening and entirely through the capping layer.

At block 722, a pair of metal lines, a second row of metal lines located between the pair of metal lines, and one or more vias are formed. In some embodiments, forming the pair of metal lines, the second row of metal lines located between the pair of metal lines, and the one or more vias comprises optionally conformally depositing (at block 724) a metal barrier material in the pair of outer line openings, the plurality of line openings located between the pair of outer line openings, and the one or more vias to form a metal barrier, followed by the deposition (at block 726) of a conductive metal material. In those embodiments in which the via opening is formed above the metal line of the first row of inner metal lines, the via extends entirely through the dielectric layer and partially through the capping layer such that the via is in contact with the metal line of the first row of inner metal lines formed in the bottom portion of the metal layer. In those embodiments in which the via opening is formed below a line opening formed in the top portion of the metal layer, the via extends entirely through the capping layer and partially through the dielectric layer such that the top of the via is in contact with the bottom of a metal line of the second row of inner metal lines located in the top portion of the metal layer.

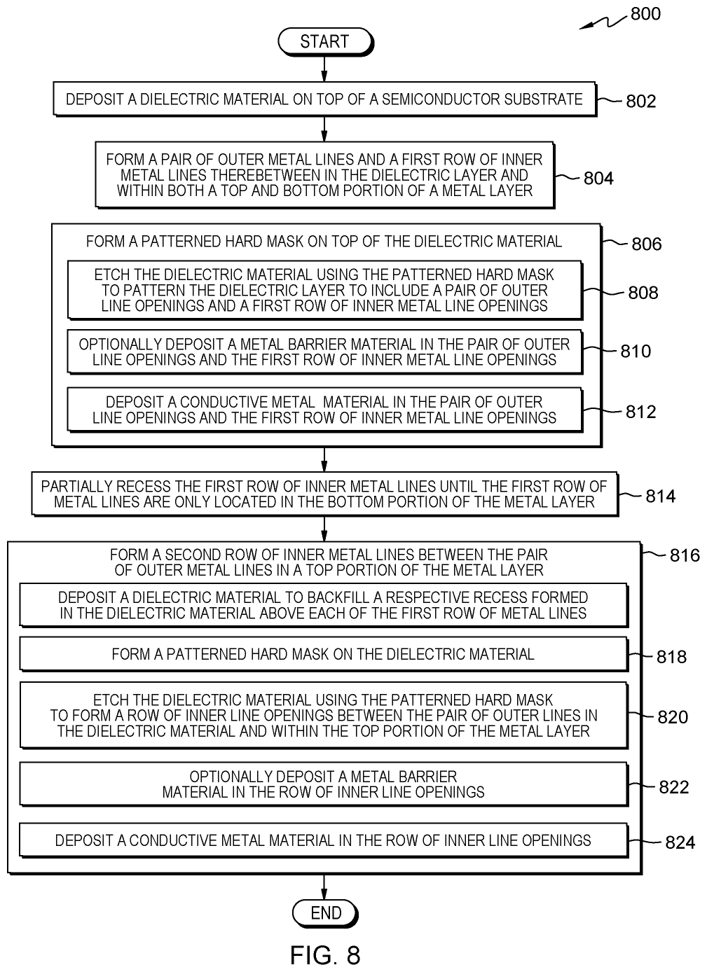

Referring now to FIG. 8, the method 800 optionally begins at block 802, where a dielectric layer is formed on top of a semiconductor substrate. At block 804, a plurality of metal lines are formed in the dielectric layer and within a metal layer using one or more damascene processes. In some embodiments, the one or more damascene processes comprise (at block 806) forming a patterned hard mask on top of the dielectric layer, etching (at block 808) the respective portions of the dielectric layer exposed by the patterned hard mask to form a patterned dielectric layer including a plurality of line openings, optionally conformally depositing (at block 810) a metal barrier material in the plurality of line openings to form a metal barrier, followed by the deposition of a conductive metal material in the plurality of line openings to form the plurality of metal lines in the metal layer at block 812.

At block 814, the inner metal lines located between a pair of outer metal lines of the plurality of metal lines are partially recessed to form a first row of inner metal lines located in a bottom portion of the metal layer and a plurality of openings in the dielectric layer located above the first row of metal lines. The pair of outer metal lines of the plurality of metal lines are not recessed, and thus remain located in both the bottom portion and a top portion of the metal layer.

At block 816, a second row of inner metal lines located between the pair of outer metal lines are formed within a top portion of the metal layer. In some embodiments, forming the second row of inner metal lines comprises (at block 818) depositing a dielectric material to backfill a recess formed in the dielectric layer above each of the first row of inner metal lines located between the pair of outer metal lines, patterning (at block 820) the dielectric material to form a plurality of line openings, optionally conformally depositing (at block 822) a metal barrier material in the plurality of line openings to form a metal barrier, and conformally depositing (at block 824) a conductive metal material in the plurality of line openings to form the second row of inner metal lines located between the pair of outer metal lines and in the top portion of the metal layer. In some embodiments, the second row of inner metal lines located in the top portion of the metal layer are horizontally staggered with respect to the first row of inner metal lines located within the bottom portion of the metal layer. In other embodiments, the second row of inner metal lines located in the top portion of the metal layer are vertically aligned with respect to the first row of inner metal lines located within the bottom portion of the metal layer.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein.

In addition, any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as, for instance, “side”, “over”, “perpendicular”, “tilted”, etc., as used herein refer to relative location and orientation of various portions of the structures with respect to one another, and are not intended to suggest that any particular absolute orientation with respect to external objects is necessary or required.

The foregoing specification also describes processing steps. While some of the steps may be in an ordered sequence, others may in different embodiments from the order that they were detailed in the foregoing specification. The ordering of steps when it occurs is explicitly expressed, for instance, by such adjectives as, “ordered”, “before”, “after”, “following”, and others with similar meaning.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art.

What is claimed is:

1. A semiconductor interconnect structure, comprising:
a first row of metal lines located in a bottom portion of a metal layer; and
a second row of metal lines located in a top portion of the metal layer, wherein the first row of metal lines are horizontally staggered with respect to the second row of metal lines.

2. The semiconductor interconnect structure of claim 1, wherein the first row of metal lines located in the bottom portion of the metal layer and the second row of metal lines located in the top portion of the metal layer are further located between a pair of outer metal lines.

3. The semiconductor interconnect structure of claim 2, wherein:
the first row of metal lines and the second row of metal lines are narrower than the pair of outer metal lines; and
the first row of metal lines and the second row of metal lines are shorter than the pair of outer metal lines.

4. The semiconductor interconnect structure of claim 2, wherein:
a bottom surface of the first row of metal lines is coplanar with a bottom surface of the outer pair of metal lines; and
a top surface of the second row of metal lines is coplanar with a top surface of the pair of outer metal lines.

5. The semiconductor interconnect structure of claim 2, wherein:
a top surface of the second row of metal lines and a top surface of the pair of outer metal lines is coplanar with a top surface of the metal layer; and
a bottom surface of the first row of metal lines and a bottom surface of the pair of outer metal lines is coplanar with a bottom surface of the metal layer.

6. The semiconductor interconnect structure of claim 2, wherein:
the first row of metal lines and the second row of metal lines are signal lines; and
the pair of outer metal lines are power lines.

7. The semiconductor interconnect structure of claim 2, wherein:
the first row of metal lines located in the bottom portion of the metal layer and the second row of metal lines located in the top portion of the metal layer are formed from the same material(s).

8. The semiconductor interconnect structure of claim 2, wherein:
the first row of metal lines located in the bottom portion of the metal layer and the second row of metal lines located in the top portion of the metal layer are formed from different material(s).

9. A semiconductor interconnect structure, comprising:
a first row of metal lines located between a pair of outer metal lines, wherein:
the first row of metal lines are formed in a bottom portion of a metal layer; and
the pair of outer metal lines are formed in both the bottom portion of the metal layer and a top portion of the metal layer.

10. The semiconductor interconnect structure of claim 9, further comprising a second row of metal lines located in a top portion of the metal layer and between the pair of outer metal lines.

11. The semiconductor interconnect structure of claim 10, wherein the second row of metal lines located in the top portion of the metal layer are horizontally staggered with respect to the first row of metal lines located in the bottom portion of the metal layer.

12. The semiconductor interconnect structure of claim 10, wherein:
the first row of metal lines and the second row of metal lines are narrower than the pair of outer metal lines; and
the first row of metal lines and the second row of metal lines are shorter than the pair of outer metal lines.

13. The semiconductor interconnect structure of claim 10, wherein:
a bottom surface of the first row of metal lines is coplanar with a bottom surface of the pair of outer metal lines; and
a top surface of the second row of metal lines is coplanar with a top surface of the pair of outer metal lines.

14. The semiconductor interconnect structure of claim 10, wherein:
a top surface of the second row of metal lines and a top surface of the pair of outer metal lines is coplanar with a top surface of the metal layer; and
a bottom surface of the first row of metal lines and a bottom surface of the pair of outer metal lines is coplanar with a bottom surface of the metal layer.

15. The semiconductor interconnect structure of claim 10, wherein:
the first row of metal lines and the second row of metal lines are signal lines; and
the pair of outer metal lines are power lines.

16. The semiconductor interconnect structure of claim 10, wherein:
the first row of metal lines located in the bottom portion of the metal layer and the second row of metal lines located in the top portion of the metal layer are formed from the same material(s).

17. The semiconductor interconnect structure of claim 10, wherein:
the first row of metal lines located in the bottom portion of the metal layer and the second row of metal lines located in the top portion of the metal layer are formed from different material(s).

18. A method of forming a semiconductor interconnect structure, comprising:
forming a plurality of metal lines in a metal layer;
forming a recess in a top portion of respective inner metal lines located between a pair of outer metal lines of the plurality of metal lines to form a first row of metal lines located within a bottom portion of the metal layer; and
forming a second row of metal lines in a top portion of the metal layer, wherein forming the second row of metal lines in the top portion of the metal layer includes:
depositing a dielectric material to backfill the recess in the top portion of the respective inner metal lines located between the pair of out metal lines;
patterning the dielectric material to form a plurality of line openings; and
depositing a conductive metal material in the plurality of line openings.

19. The method of claim 18, wherein the dielectric material is patterned such that the plurality of line openings are horizontally staggered with respect to the first row of metal lines located within the bottom portion of the metal layer.

20. The method of claim 19, wherein the dielectric material is patterned such that the plurality of lines opening are vertically aligned with respect to the first row of metal lines located within the bottom portion of the metal layer.
